(19) United States
(12) Patent Application Publication
(10) Pub. No.: US 2026/0223712 A1
(43) Pub. Date: Jul. 30, 2026

(54) SEMICONDUCTOR DEVICE AND RESIN COMPOSITION

(71) Applicant: NAMICS CORPORATION, Niigata-shi, Niigata (JP)

(72) Inventors: Kaori HAMADA, Niigata-shi (JP); Masaki YOSHIDA, Niigata-shi (JP)

(21) Appl. No.: 19/157,917

(22) PCT Filed: Feb. 28, 2024
(86) PCT No.: PCT/JP2024/007249

§ 371 Date: Aug. 19, 2025

(30) Foreign Application Priority Data
Mar. 10, 2023 (JP) 2023-037498

(51) Int. Cl. H10W 70/695; H10W 70/652; H10W 74/10; H10W 74/47; H10W 90/00

(52) U.S. Cl. CPC H10W 70/695; H10W 70/652; H10W 74/473; H10W 90/794; H10W 74/117

(57) ABSTRACT

Provided are a semiconductor device including an interlayer insulating film having a large tensile elongation and a resin composition. A semiconductor device including a semiconductor chip, an encapsulation material for covering the semiconductor chip, and a rewiring layer including a wiring for electrically connecting the semiconductor chip and an external terminal, and an interlayer insulating film for covering a portion around the wiring, in which the rewiring layer has an area larger than that of the semiconductor chip in a plan view, and in which the interlayer insulating film has a tensile elongation of 15% or more at 25° C.

### CROSS-REFERENCE TO RELATED APPLICATION

This application is a national stage entry of International Application No. PCT/JP2024/007249, filed on Feb. 28, 2024, which claims priority to Japanese Patent Application No. 2023-037498, filed on Mar. 10, 2023. The entire disclosures of the above applications are incorporated herein by reference.

### BACKGROUND

### Technical Field

The present invention relates to a semiconductor device and a resin composition.

### Related Art

Electronic devices are being reduced in the size and weight and improved in the functions, and hence a semiconductor package used in the electronic devices is required to be further downsized and more lightweight and to be mounted on a printed circuit board with high mounting density. Under the circumstances, a technique for semiconductor package called a wafer level chip size package (WL-CSP) or wafer level package (WLP) has been proposed. The WL-CSP or WLP indicates a semiconductor package which has not been subjected to internal wiring by bonding wire and thus has left part of a semiconductor substrate (silicon wafer) exposed, and which has a size almost equivalent to that of the semiconductor substrate.

There are a WLP of a fan-in type and a WLP of a fan-out type. The WLP of a fan-in type has an external electrode (external terminal) as a semiconductor device provided in a region equivalent to the size of a semiconductor chip. For example, in the WLP of a fan-in type, a rewiring layer comprising a wiring and an interlayer insulating film is formed in a region equivalent to a semiconductor chip, and an external electrode (external terminal) is provided. The WLP of a fan-out type has an external electrode (external terminal) as a semiconductor device provided in a region larger than the size of a semiconductor chip. In a semiconductor device of a fan-out WLP type (hereinafter, frequently referred to as “FO-WLP type”), a semiconductor chip is encapsulated with an encapsulation material comprising a resin, and a rewiring layer comprising a wiring and an interlayer insulating film is formed in a region which is larger than the semiconductor chip, and which is in contact with both the semiconductor chip and the encapsulation material encapsulating the semiconductor chip, and an external electrode (external terminal) is provided.

For example, JP 2019-29555 A (PTL 1) discloses a semiconductor device of an FO-WLP type, which comprises a semiconductor chip, an encapsulation material for covering the semiconductor chip, and a rewiring layer having an area larger than that of the semiconductor chip in a plan view.

The rewiring layer provided in a semiconductor device of an FO-WLP type encounters a problem in that the semiconductor chip and the encapsulation material are different materials having different coefficients of linear expansion and a difference of the coefficient of linear expansion between the materials likely causes the semiconductor chip, the encapsulation material, and the like to suffer removal in thermal cycling that repeats a change of a high temperature and a low temperature. The rewiring layer is in contact with the semiconductor chip and the encapsulation material which are two different materials having different coefficients of linear expansion, and hence the rewiring layer is likely to be removed due to a difference of the coefficient of linear expansion between the semiconductor chip and the encapsulation material when the thermal cycling is repeated, so that a crack is easily formed in the wiring contained in the rewiring layer.

Accordingly, an object of the present invention is to provide a semiconductor device comprising an interlayer insulating film having such a large tensile elongation that even when the interlayer insulating film is in contact with two materials having different coefficients of linear expansion, a removal of the materials or formation of a crack due to a difference of the coefficient of linear expansion can be suppressed, and a resin composition.

### SUMMARY

A means for solving the above-mentioned problems is as described below, and the present invention encompasses the following embodiments.

[1] A semiconductor device comprising:
a semiconductor chip,
an encapsulation material for covering the semiconductor chip, and
a rewiring layer comprising a wiring for electrically connecting the semiconductor chip and an external terminal, and an interlayer insulating film for covering a portion around the wiring,
in which the rewiring layer has an area larger than that of the semiconductor chip in a plan view, and
in which the interlayer insulating film has a tensile elongation of 15% or more at 25° C.

[2] The semiconductor device according to item [1] above, in which the interlayer insulating film is directly in contact with at least part of the semiconductor chip and at least part of the encapsulation material.

[3] The semiconductor device according to item [1] or [2] above, in which at least part of the semiconductor chip and at least part of the encapsulation material are adjacent to each other and present on the same plane, in which the interlayer insulating film is directly in contact with at least part of the semiconductor chip and at least part of the encapsulation material which are present on the same plane.

[4] The semiconductor device according to any of items [1] to [3] above, in which the interlayer insulating film has a dielectric loss tangent (tan δ) of 0.010 or less, as measured at a dielectric resonance frequency of 10 GHz.

[5] The semiconductor device according to any of items [1] to [4] above, in which the interlayer insulating film is formed from a resin composition comprising a thermosetting resin having an unsaturated double bond at the end thereof.

[6] The semiconductor device according to any of items [1] to [5] above, in which the interlayer insulating film is formed from a resin composition comprising a polyphenylene ether having an unsaturated double bond at the end thereof, and an elastomer.

[7] The semiconductor device according to any of items [1] to [6] above, in which the interlayer insulating film is formed from a resin composition comprising a polyphenylene ether having an unsaturated double bond at the end thereof, and an elastomer, in which the ratio of a hard segment and a soft segment contained in the elastomer is 1:99 to 45:55.

[8] The semiconductor device according to item [6] or [7] above, in which the elastomer is a styrene thermoplastic elastomer.

[9] The semiconductor device according to any of items [1] to [8] above, in which the encapsulation material comprises an epoxy resin.

[10] A resin composition for a semiconductor device of a wafer level package type, the resin composition comprising:
(A) a thermosetting resin having an unsaturated double bond at the end thereof, and
(B) an elastomer,
in which a cured product of the resin composition has a tensile elongation of 15% or more at 25° C.

[11] The resin composition according to item [10] above, further comprising (C) a solvent.

[12] The resin composition according to item [11] above, which has a first viscosity in the range of from 300 to 4,000 mPa·s, as measured at 25° C. and at 10 rpm using a rotational viscometer.

[13] The resin composition according to item [12] above, which has a second viscosity in the range of from 200 to 4,200 mPa·s, as measured at 25° C. and at 1 rpm using a rotational viscometer, and which has a thixotropy index TI of 0.5 to 3.0, in terms of the ratio of the second viscosity to the first viscosity.

[14] The resin composition according to any of items [10] to [13] above, in which the amount of the component (B) contained in the resin composition is 25 to 90% by mass, based on the total mass of the components (A) and (B) (100% by mass).

[15] A semiconductor device comprising an interlayer insulating film obtained by curing the resin composition according to any of items [10] to [14] above, which is placed around a wiring for electrically connecting a semiconductor chip and an external terminal.

### Advantageous Effects of Invention

In the present invention, there can be provided a semiconductor device comprising an interlayer insulating film having such a large tensile elongation that even when the interlayer insulating film is in contact with two materials having different coefficients of linear expansion, a removal of the materials or formation of a crack due to a difference of the coefficient of linear expansion can be suppressed, and a resin composition.

### BRIEF DESCRIPTION OF THE DRAWINGS

FIG. 1 is a diagrammatic cross-sectional view diagrammatically showing the construction of a semiconductor device of an FO-WLP type.

FIG. 2 is a plan view of the semiconductor chip and interlayer insulating film of a semiconductor device of an FO-WLP type.

FIG. 3 is a diagrammatic perspective view showing a semiconductor device of an FO-WLP type in a state such that the semiconductor chip and encapsulation material are separated from the rewiring layer.

FIG. 4 is a diagrammatic perspective view of the semiconductor chip and encapsulation material of a semiconductor device of an FO-WLP type.

### DETAILED DESCRIPTION

Hereinbelow, the semiconductor device and resin composition of the present disclosure will be described with reference to the following embodiments. The present disclosure may include an interlayer insulating film for the semiconductor device, which is obtained by curing the resin composition. The embodiments described below are examples for specifying the technical idea of the present invention, and the below-described semiconductor device and resin composition and the interlayer insulating film for the semiconductor device should not be construed as limiting the scope of the present invention. In the present description, the range of values indicated using the preposition “to” means a range of values including the respective values or symbols having the values shown before and after the preposition “to” as the lower limit value and the upper limit value, and represents from “or more” to “or less”. Further, the members shown in the scope of claims are not limited to the members described in the embodiments. Particularly, the dimension, material, form, arrangement, and the like of the members described in the embodiments are not intended to limit the range of the present disclosure only thereto unless otherwise specified, but are merely examples for explanation. With respect to the members shown in the drawings, the size and positions may be exaggerated, and the form may be simplified, and the scale may vary depending on the drawing.

The semiconductor device according to an embodiment of the present invention comprises a semiconductor chip, an encapsulation material for covering the semiconductor chip, and a rewiring layer comprising a wiring for electrically connecting the semiconductor chip and an external terminal, and an interlayer insulating film for covering a portion around the wiring, in which the rewiring layer has an area larger than that of the semiconductor chip in a plan view, and in which the interlayer insulating film has a tensile elongation of 15% or more at 25° C. In the semiconductor device, the rewiring layer has an area larger than that of the semiconductor chip in a plan view, and therefore it is preferred that the rewiring layer is directly in contact with at least part of the semiconductor chip and at least part of the encapsulation material. At least part of the semiconductor chip and at least part of the encapsulation material are adjacent to each other and present on the same plane, and the interlayer insulating film may be directly in contact with at least part of the semiconductor chip and at least part of the encapsulation material which are present on the same plane. The interlayer insulating film of the rewiring layer has a tensile elongation of 15% or more at 25° C., and therefore the semiconductor chip and the encapsulation material have different coefficients of linear expansion and it is possible to suppress a removal of the semiconductor chip and the encapsulation material which are different materials due to expansion and shrinkage caused by thermal cycling that repeats a temperature change from ordinary room temperature which is a relatively low temperature to a relatively high temperature when the semiconductor device is operating, and formation of a crack in the wiring contained in the rewiring layer and the like can be suppressed. In the semiconductor device, the interlayer insulating film of the rewiring layer has a tensile elongation at 25° C. of 15% or more, preferably 20% or more, more preferably 25% or more, further preferably 30% or more. From the viewpoint of suppressing an effect of plastic deformation of the interlayer insulating film even when being in contact with the semiconductor chip and the encapsulation material which are two materials having different coefficients of linear expansion, the interlayer insulating film of the rewiring layer in the semiconductor device may have a tensile elongation of 500% or less at 25° C., and the tensile elongation may be 480% or less, preferably 450% or less, and may be 400% or less, and may be 350% or less. That is, the interlayer insulating film of the rewiring layer in the semiconductor device preferably has a tensile elongation at 25° C. of 15 to 500%, more preferably 20 to 480%, further preferably 25 to 450%, especially preferably 30 to 350%.

The tensile elongation of the interlayer insulating film of the rewiring layer in the semiconductor device can be measured using a resin composition that can constitute an interlayer insulating film for a semiconductor device of an FO-WLP type, using a table top precision universal testing machine (for example, Autograph AGS-J series, manufactured by Shimadzu Corporation), and using a test specimen (film sample) in a strip form having a width of 15 mm, a length of 200 mm, and a thickness of 30 μm.

The tensile elongation of the interlayer insulating film of the rewiring layer in the semiconductor device can be determined by producing a test specimen with a size having a width of 15 mm, a length of 200 mm, and a thickness of 30 μm using a cured product which is obtained by curing a resin composition that can constitute an interlayer insulating film for a semiconductor device, and fixing the test specimen by upper and lower fixtures of a table-top precision universal testing machine so that a length between the fixtures becomes 100 mm, and pulling the test specimen upwardly at a speed of 200 mm/minute, and determining a tensile elongation calculated using the following formula (1) from a length at break as a tensile elongation of the interlayer insulating film of the rewiring layer in the semiconductor device.

$$Tensile elongation ( \% ) = [ Length at break ( mm ) - Initial length ( 100 mm ) ] / Initial length ( 100 mm ) \times 100 \qquad ( 1 )$$

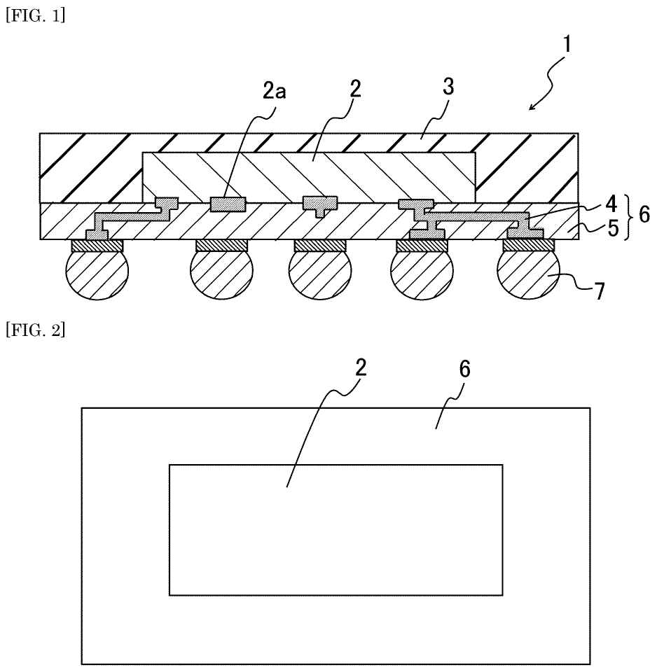

FIG. 1 is a diagrammatic cross-sectional view diagrammatically showing the construction of a semiconductor device of an FO-WLP type, which is an example of a semiconductor device. A semiconductor device 1 comprises a semiconductor chip 2, an encapsulation material 3 (molding resin) for covering the semiconductor chip 2, and a rewiring layer 6 comprising a wiring 4 for connecting the semiconductor chip 2 and an external terminal 7, and an interlayer insulating film 5 for covering a portion around the wiring 4. FIG. 2 is a plan view of the rewiring layer 6 and semiconductor chip 2, and the encapsulation material 3 is not shown, and the rewiring layer 6 has an area larger than that of the semiconductor chip 2 in a plan view. The rewiring layer 6 is directly in contact with at least part of the semiconductor chip 2 and at least part of the encapsulation material 3, and particularly, the interlayer insulating film 5 of the rewiring layer 6 is directly in contact with both at least part of the semiconductor chip 2 and at least part of the encapsulation material 3.

The semiconductor chip 2 is provided with a plurality of terminals 2a. The terminals 2a provided in the semiconductor chip 2 are electrically connected to the wiring 4 of the rewiring layer 6. One end of the wiring 4 is connected to the terminals 2a of the semiconductor chip 2, and another end of the wiring 4 is connected to an external terminal 7, such as a solder pump. A portion around the wiring 4 is covered with the interlayer insulating film 5.

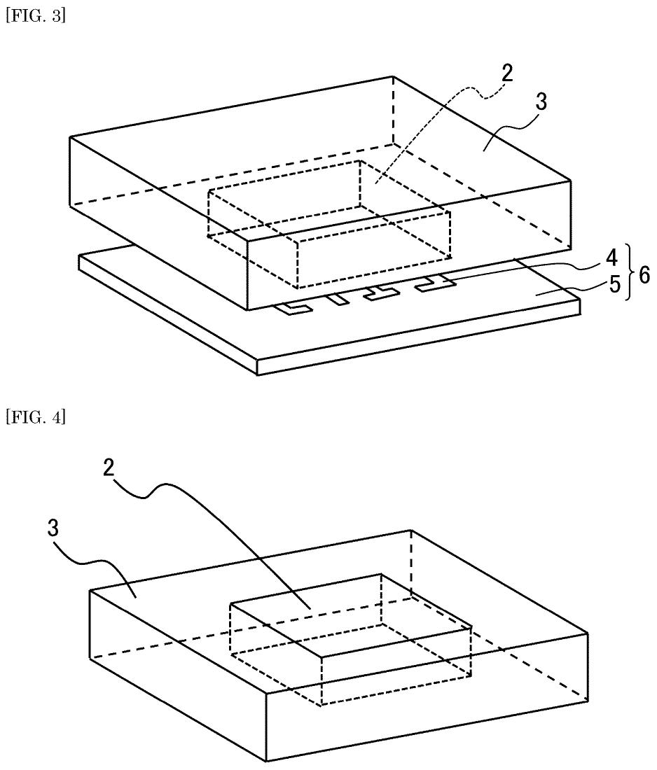

FIG. 3 is a diagrammatic perspective view showing a part of the construction of a semiconductor device, and shows a semiconductor chip 2, an encapsulation material 3 for covering the semiconductor chip 2, and a rewiring layer 6 in a state such that the semiconductor chip 2 and the encapsulation material 3 are separated from each other. FIG. 4 is a diagrammatic perspective view showing the semiconductor chip 2 for use in a semiconductor device of an FO-WLP type and the encapsulation material 3 for covering the semiconductor chip 2, which is adjacent to the semiconductor chip 2, as viewed from the side that the semiconductor chip 2 and the encapsulation material 3 can be seen as being present on the same plane. In FIG. 4, a terminal and the like for the semiconductor chip 2 are not shown. As shown in FIG. 1 or 4, it is preferred that at least part of the semiconductor chip 2 and at least part of the encapsulation material 3 are adjacent to each other and present on the same plane, and it is preferred that the interlayer insulating film 5 of the rewiring layer 6 is directly in contact with at least part of the semiconductor chip 2 and at least part of the encapsulation material 3 adjacent to the semiconductor chip 2, which are present on the same plane. When the interlayer insulating film 5 having a tensile elongation of 15% or more is in contact with both at least part of the semiconductor chip 2 and at least part of the encapsulation material 3 which are adjacent to each other and present on the same plane, the semiconductor chip 2 and the encapsulation material 3 having different coefficients of linear expansion expand and shrink due to thermal cycling that repeats a temperature change from ordinary room temperature which is a relatively low temperature to a relatively high temperature when the semiconductor device is operating, and the interlayer insulating film 5 absorbs expansion and shrinkage of the different materials having different coefficients of linear expansion, so that a removal of the semiconductor chip 2 and the encapsulation material 3 is suppressed, and formation of a crack in the wiring 4 contained in the rewiring layer 6 and the like can be also suppressed.

With respect to the semiconductor chip, one which is formed from silicon or the like can be used, and a semiconductor chip having a circuit formed therein can be used.

With respect to the encapsulation material, there is no particular limitation, but the encapsulation material preferably comprises an epoxy resin, more preferably contains an inorganic filler, such as silicon dioxide. Further, from the viewpoint of suppressing a removal of the semiconductor chip and the encapsulation material, the encapsulation material preferably has a coefficient of linear expansion (CTEα1) in the range of from 10 to 30 ppm/° C., more preferably in the range of from 10 to 20 ppm/° C., further preferably in the range of from 6 to 20 ppm/° C. at a temperature lower than the glass transition temperature of the encapsulation material.

A coefficient of linear expansion (CTEα1) of the encapsulation material at a temperature lower than the glass transition temperature of the encapsulation material can be measured by producing a test specimen having a cylindrical shape of 8 mmφ (diameter: 8 mm)×height: 20 mm, and curing the test specimen at 150° C. for one hour, and then conducting measurement using a thermomechanical analyzer in a compression mode under conditions such that the measurement temperature is in the range of from −30 to 220° C. and the temperature increase rate is 10° C./minute, and calculating an average coefficient of linear expansion at 50 to 70° C. from the results of the measurement and determining the calculated value as a coefficient of linear expansion (CTEα1) at a temperature lower than the glass transition temperature.

The rewiring layer has an area larger than that of the semiconductor chip in a plan view, and the area S1 of the rewiring layer in a plan view is preferably 1.05 times or more, more preferably 1.1 times or more, further preferably 1.2 times or more, still further preferably 1.3 times or more the area S2 of the semiconductor chip in a plan view. The area S1 of the rewiring layer in a plan view may be 50 times or less the area S2 of the semiconductor chip in a plan view, and may be 25 times or less, and may be 10 times or less. The area S1 of the rewiring layer in a plan view may be the same as the area S3 of the encapsulation material in a plan view. The form of the rewiring layer in a plan view may be the same as, different from, or analogous to the form of the semiconductor chip in a plan view.

The rewiring layer may be of a single layer, or may have a structure in which two or more layers are stacked. The rewiring layer may contain a layer comprised only of the wiring, a layer comprised only of the interlayer insulating film, and a layer comprised of the wiring and the interlayer insulating film covering a portion around the wiring.

In the semiconductor device of an FO-WLP type, the semiconductor chip and an external terminal are connected by the rewiring layer to achieve direct electrical conduction to a mother board. Differing from a semiconductor device of a flip chip ball grid array (FC-BGA) type or the like, the semiconductor device of an FO-WLP type does not need electrical conduction to a mother board through an interposer or a printed wiring board, and can be reduced in the thickness of the semiconductor device, as compared to a semiconductor device of an FC-BGA type.

The thickness of the rewiring layer may be 1 μm or more, may be 2 μm or more, may be 3 μm or more, may be 5 μm or more, and may be 10 μm or more, and may be 40 μm or less, may be 30 μm or less, and may be 20 μm or less.

With respect to the wiring, any member having high electrical conductivity can be used, and, for example, copper is used.

The interlayer insulating film can be formed by placing the below-described resin composition for a semiconductor device of an FO-WLP type around the wiring for electrically connecting the semiconductor chip and an external terminal, and curing the resin composition. The rewiring layer comprises a wiring for electrically connecting the semiconductor chip and an external terminal, and an interlayer insulating film obtained by curing the resin composition placed around the wiring.

Hereinbelow, the components contained in the interlayer insulating film for a semiconductor device or the components contained in the resin composition for the interlayer insulating film are described. In the present description, according to the usual practice in the field of synthetic resin, with respect to the components constituting the resin composition, the term “resin” generally means a “polymer”, and a name including “resin” that is a term generally indicating a polymer (particularly, a synthetic polymer) may be used even when the component is not a polymer.

It is preferred that the interlayer insulating film is formed from a resin composition comprising a thermosetting resin having an unsaturated double bond at the end thereof. In the resin composition for the interlayer insulating film for a semiconductor device of an FO-WLP type, the thermosetting resin having an unsaturated double bond at the end thereof is frequently referred to as “component (A)” or “thermosetting resin as component (A)”.

It is preferred that the interlayer insulating film is formed from a resin composition comprising a polyphenylene ether having an unsaturated double bond at the end thereof, and an elastomer. In the resin composition for the interlayer insulating film for a semiconductor device of an FO-WLP type, the elastomer is frequently referred to as “component (B)” or “elastomer as component (B)”.

It is preferred that the resin composition for the interlayer insulating film for a semiconductor device of an FO-WLP type further comprises (C) a solvent. In the resin composition for the interlayer insulating film for a semiconductor device of an FO-WLP type, the solvent is frequently referred to as “component (C)” or “solvent as component (C)”.

As the speed of data transmission is increasingly becoming higher and the capacity of the data transmitted is being increased, electronic parts are required to have high frequency properties. A semiconductor device of an FO-WLP type used in the electronic parts is also needed to have high-frequency properties. For example, in a high frequency region, specifically, in the frequency region of 1 to 10 GHz, the semiconductor device of an FO-WLP type is required to have excellent electrical properties (low permittivity (e) and low dielectric loss tangent (tan δ)).

When the interlayer insulating film or the resin composition for the interlayer insulating film contains a thermosetting resin as component (A) having an unsaturated double bond at the end thereof, a cured product obtained by curing the resin composition has low dielectric properties imparted thereto, and further can be improved in heat resistance. As an example of the functional group having an unsaturated double bond at the end thereof, there can be mentioned a vinyl group, a vinylbenzyl group, a vinylene group, a vinylidene group, an acryl group, or a methacryl group. The thermosetting resin having an unsaturated double bond at the end thereof is preferably a polyphenylene ether resin having at the end thereof a functional group containing an unsaturated double bond. The polyphenylene ether resin is frequently referred to as “PPE resin”. With respect to the component (A), there is no particular limitation as long as it has at the end thereof a functional group containing an unsaturated double bond and has polyphenylene ether in the skeleton. The component (A) is especially preferably a polyphenylene ether resin having a vinyl group or a styrene group at the end thereof. By virtue of having a vinyl group or a styrene group at the end thereof, the resin can obtain low dielectric properties. When the thermosetting resin having an unsaturated double bond at the end thereof is a polyphenylene ether resin, the component (A) in the resin composition for the interlayer insulating film is frequently referred to as “polyphenylene ether resin as component (A)”.

The PPE resin as component (A) preferably comprises a PPE resin represented by the following formula (1):

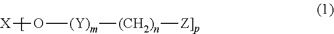

wherein X represents a p-valent unsubstituted or substituted aromatic hydrocarbon group,
Y represents an unsubstituted or substituted phenol repeating unit represented by the following formula (2):

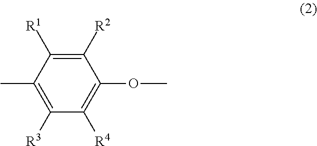

wherein each of R¹ to R⁴ independently represents a hydrogen atom, an alkyl group, an alkenyl group, an alkynyl group, or an alkenylcarbonyl group,
Z is a terminal functional group having an unsaturated double bond, and represents a vinyl group, a vinylene group, (a) an (meth)acryl group represented by the following formula (3):

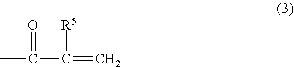

wherein R⁵ represents a hydrogen atom or an alkyl group, or a styrene group represented by the following formula (4):

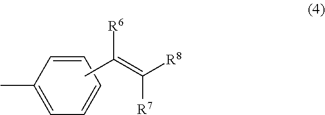

wherein each of R⁶ to R⁸ independently represents a hydrogen atom, an alkyl group, an alkenyl group, or an alkynyl group,
m represents an integer of 1 to 100,
n represents 0 or an integer of 1 to 6, and
p represents an integer of 1 to 4.

The PPE resin as component (A) preferably comprises at least one member selected from the group consisting of a modified PPE resin represented by the following formula (5) and a modified PPE resin represented by the following formula (6):

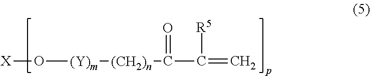

wherein R⁵ represents a hydrogen atom or an alkyl group,
X represents a p-valent unsubstituted or substituted aromatic hydrocarbon group,
Y represents an unsubstituted or substituted phenol repeating unit represented by the formula (2) above,
m represents an integer of 1 to 100,
n represents 0 or an integer of 1 to 6, and
p represents an integer of 1 to 4,

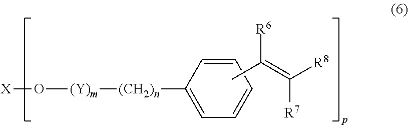

wherein each of R⁶ to R⁸ independently represents a hydrogen atom, an alkyl group, an alkenyl group, or an alkynyl group,
X represents a p-valent unsubstituted or substituted aromatic hydrocarbon group,
Y represents an unsubstituted or substituted phenol repeating unit represented by the formula (2) above,
m represents an integer of 1 to 100,
n represents 0 or an integer of 1 to 6, and
p represents an integer of 1 to 4.

Generally, an x-valent (in which x represents an integer of 1 or more) hydrocarbon group indicates an x-valent group obtained by removing x hydrogen atom or atoms from the carbon atom or atoms of a hydrocarbon. X indicates a p-valent unsubstituted or substituted aromatic hydrocarbon group, which is a mono-, di-, tri-, or tetra-valent group obtained by removing 1 to 4 hydrogen atoms from the carbon atom or atoms of an unsubstituted or substituted aromatic hydrocarbon.

The term “alkyl group” means a monovalent saturated hydrocarbon group. In the present invention, when the number of carbon atoms of the alkyl group is not shown, the alkyl group is preferably a C₁-C₁₀ alkyl group, more preferably a C₁-C₆ alkyl group, further preferably a C₁-C₄ alkyl group, especially preferably a C₁-C₂ alkyl group. Examples of such alkyl groups include a methyl group, an ethyl group, a propyl group, an isopropyl group, a butyl group, an isobutyl group, a sec-butyl group, a tert-butyl group, a pentyl group, and a hexyl group. The C₁ alkyl group indicates an alkyl group having one carbon atom (methyl group). In the present description, the figure shown after “C” used for representing a saturated hydrocarbon group or an unsaturated hydrocarbon group indicates the number of carbon atom or atoms contained in the saturated hydrocarbon group or unsaturated hydrocarbon group. Further, the symbol “-” shown between “C” and “C” indicates a range between the figures shown after the respective C's. For example, the “C₁-C₁₀ alkyl group” means an “alkyl group having 1 to 10 carbon atoms”.

The term “alkenyl group” means a monovalent unsaturated hydrocarbon group having at least one carbon-carbon double bond. In the present invention, the alkenyl group is preferably a C₂-C₁₀ alkenyl group, more preferably a C₂-C₆ alkenyl group, further preferably a C₂-C₄ alkenyl group. Examples of such alkenyl groups include an ethenyl group (vinyl group), a 1-propenyl group, a 2-propenyl group, a 1-butenyl group, a 2-butenyl group, an isobutenyl group, a 1-pentenyl group, and a 1-hexenyl group. The group-CR⁵═CH₂ and group-CR⁶═CR⁷R⁸ in the formula above are also an alkenyl group.

The term “alkynyl group” means a monovalent unsaturated hydrocarbon group having at least one carbon-carbon triple bond. In the present invention, the alkynyl group is preferably a C₂-C₁₀ alkynyl group, more preferably a C₂-C₆ alkynyl group, further preferably a C₂-C₄ alkynyl group. Examples of such alkynyl groups include an ethynyl group, a 1-propynyl group, a 2-propynyl group, a butynyl group, an isobutynyl group, a pentynyl group, and a hexynyl group.

The term “alkenylcarbonyl group” means a carbonyl group substituted with the above-mentioned alkenyl group, and examples of such groups include an acryl group and a methacryl group.

With respect to the component (A), in the formula (1), (5), or (6), the portion represented by —(Y) m-corresponds to the principal chain of the PPE resin. It is preferred that, in unsubstituted or substituted phenol repeating unit Y, R¹ and R³ represent a hydrogen atom and R² and R⁴ represent a methyl group. In the formula (1), one end of the portion represented by —(Y)ₘ— is bonded to an aromatic hydrocarbon group X through an oxygen atom, and another end is bonded through n methylene group or groups to an end group (Z) which represents a functional group having an unsaturated double bond. In the formula (5), one end of the portion represented by —(Y)ₘ— is bonded to an aromatic hydrocarbon group X through an oxygen atom, and another end is bonded to a methacryloyl group through n methylene group or groups. In the formula (6), one end of the portion represented by —(Y)ₘ is bonded to an aromatic hydrocarbon group X through an oxygen atom, and another end is bonded to a styrene group through n methylene group or groups. In the styrene group of the formula (6), the portion represented by −CR⁶═CR⁷R⁸ may be present at any of the ortho-position, meta-position, and para-position with respect to the methylene group. In one mode, n in the formula (1), (5), or (6) is 0 or an integer of 1 to 4. In another mode, n in the formula (1), (5), or (6) is 0, 1, or 2. In another mode, n in the formula (1) is 0 or 1. In still another mode, all of R⁶ to R⁸ in the formula (6) are a hydrogen atom.

Further, m in the formula (1), (5), or (6), which is the number of repeating units Y, is preferably 1 to 80, more preferably 1 to 30, further preferably 1 to 5.

In the component (A), p portions represented by —(Y)ₘ— are bonded to the aromatic hydrocarbon group X in the formula (1), (5), or (6) through an oxygen atom. p is preferably 2 or 3. p is more preferably 2. X is preferably represented by the following formula (7) or (8):

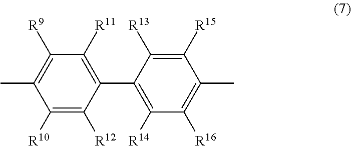

wherein each of R⁹ to R¹⁶ independently represents a hydrogen atom, a C₁-C₆ alkyl group, or a phenyl group,

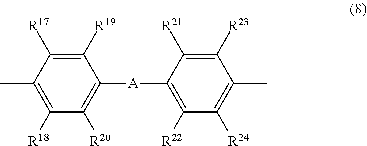

wherein each of R¹⁷ to R²⁴ independently represents a hydrogen atom, a C₁-C₆ alkyl group, a phenyl group, or a naphthyl group, and A represents a C₀-C₂₀ linear, branched, or cyclic divalent hydrocarbon group,
   And X May More Preferably have a Structure Represented by the Following Formula:

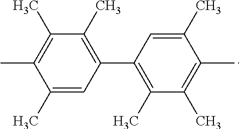

Specific examples of A's in the formula (8) include divalent hydrocarbon groups, such as methylene, ethylidene, 1-methylethylidene, 1,1-propylidene, 1,4-phenylenebis(1-methylethylidene), 1,3-phenylenebis(1-methylethylidene), Cyclohexylidene, phenylmethylene, naphthylmethylene, and 1-phenylethylidene.

With respect to the end of the principal chain of the polyphenylene ether resin as component (A), the polyphenylene ether resin may be a polyphenylene ether resin having 1.5 to 5 functional groups represented by the formula (1), (5), or (6) on average per molecule at the end of the principal chain. The terminal functional group is preferably a methacryl group and/or an acryl group from the viewpoint of imparting further excellent heat resistance to a cured product of the resin composition, and is more preferably a methacryl group from the viewpoint of achieving further excellent resin fluidity during heat forming.

The thermosetting resin having an unsaturated double bond at the end thereof contained in the resin composition used for the interlayer insulating film is preferably a thermosetting resin having a styrene group at the end thereof and having a phenylene ether skeleton at the principal chain thereof. Preferred is a compound represented by the formula (9) below because the effects of the present invention can be more easily obtained, and excellent high frequency properties are achieved and, with respect to the temperature dependency of the dielectric properties (particularly, tan δ), the measured value at a high temperature (120° C.) is small, as compared to the measured value at ordinary room temperature (about 25° C.).

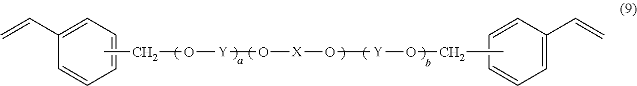

In the formula (9), X is represented by the formula (7) or (8) above.

In the formula (9), —(Y—O)— is represented by the formula (2) above.

In the formula (9), —(O—Y)— is represented by the following formula (2′).

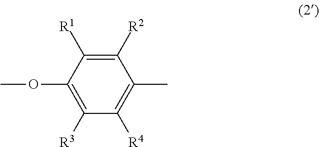

In the formula (9), a and b represent an integer of 0 to 100 and at least one of a and b is not 0.

In the production of FO-WLP, in some cases, an interlayer insulating film is formed by applying the resin composition for an interlayer insulating film onto the semiconductor chip and encapsulation material using a spin coater which is of a rotary type. Therefore, it is desired that when the resin composition for an interlayer insulating film is applied to the semiconductor chip and encapsulation material using a spin coater, a uniform film can be formed on the semiconductor chip and encapsulation material, and the formed film is unlikely to cause warpage of the semiconductor chip and the encapsulation material due to shrinkage or the like when curing the film of the resin composition.

From the viewpoint of easy application of the resin composition, for example, using a spin coater, electrical properties of the interlayer insulating film formed from the resin composition, such as low permittivity and low dielectric loss tangent, compatibility with the other components contained in the resin composition, and the like, further, the component (A) preferably has a number average molecular weight of 500 to 5,000. The number average molecular weight of the component (A) is more preferably 750 to 3,500, further preferably 800 to 3,000, still further preferably 1,000 to 2,500. When the number average molecular weight (Mn) of the component (A) is too small, it is likely that the interlayer insulating film obtained by curing the resin composition is reduced in toughness. On the other hand, when the number average molecular weight (Mn) of the component (A) is too large, it is likely that the compatibility of the component (A) with the solvent as component (C) is reduced, making it difficult to apply the resin composition to the semiconductor chip and encapsulation material using, for example, a spin coater. The number average molecular weight (Mn) of the component (A) or component (B) can be determined from, for example, a polystyrene converted value obtained by measurement of gel permeation chromatography (GPC). In the present description, the number average molecular weight (Mn) can be measured, for example, using high performance liquid chromatography (for example, LC-20AD, manufactured by Shimadzu Corporation) and using a column (for example, KF-802, manufactured by Showa Denko K.K.) and a tetrahydrofuran (THF) solution as a solvent.

With respect to the component (A), a commercially available product can be used. As a commercially available product of the component (A), which is a modified PPE resin represented by the formula (5), for example, a modified PPE resin having 1.5 to 5 terminal methacryloyl groups represented by the formula (3) per molecule, for example, trade name “NORYL SA9000”, manufactured by SABIC Innovative Plastics Japan LLC., can be used. As a commercially available product of the component (A), which is a modified PPE resin represented by the formula (6), for example, OPE 2st 1200, or OPE 2st 2200 (manufactured by Mitsubishi Gas Chemical Company, Inc.) can be used. The component (A) can be prepared by a known method. For example, the component (A) can be prepared by a method which comprises subjecting an appropriate p-valent phenol (such as 2,2′,3,3′,5,5′-hexamethylbiphenyl-4,4′-diol) having a structure represented by the formula: X—(OH)ₚ (in which X and p are as defined above) and an appropriate monovalent phenol (such as 2,6-dimethylphenol) having a structure represented by the following formula (2″):

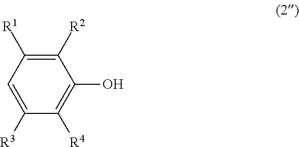

wherein R¹ to R⁴ are as defined above
   to oxidative copolymerization by a known method to prepare a polyphenylene ether resin having a hydroxyl group at the end thereof, and modifying the obtained resin through a reaction with an appropriate modifier, for example, chloromethylstyrene.

The interlayer insulating film preferably contains an elastomer. The elastomer in the present invention means, in one mode, a material (specifically, a natural or synthetic polymer material) which is elastic at room temperature (23 to 25° C.). Specific examples of elastomers include a thermosetting elastomer, a thermoplastic elastomer, a natural rubber, a synthetic rubber, a conjugated diene compound polymer, an aromatic compound-conjugated diene copolymer, a hydrogenation product of an aromatic compound-conjugated diene copolymer, a polystyrene elastomer, a polyolefin elastomer, a polyester elastomer, a polyurethane elastomer, a polyamide elastomer, and an elastomer having a core-shell structure. It is preferred that the interlayer insulating film is formed from a resin composition comprising a thermosetting resin having an unsaturated double bond at the end thereof, and an elastomer. In the resin composition for a semiconductor device of an FO-WLP type, the elastomer is frequently referred to as “component (B)” or “elastomer as component (B)”. When the interlayer insulating film or the resin composition for the interlayer insulating film contains the elastomer as component (B), a rewiring layer comprising an interlayer insulating film having a tensile elongation of 15% or more at 25° C. can be obtained. With respect to the resin composition for a semiconductor device of an FO-WLP type, by virtue of containing the thermosetting resin as component (A), the resin composition has low dielectric properties and can be easily applied using a spin coater, and, by virtue of containing the elastomer as component (B), an interlayer insulating film having a tensile elongation of 15% or more at 25° C. can be obtained from the resin composition.

It is preferred that the elastomer as component (B) is a block copolymer comprising a hard segment and a soft segment, and it is preferred that the ratio of the hard segment and the soft segment contained in the elastomer (hard segment:soft segment) is 1:99 to 45:55. When the ratio of the hard segment and the soft segment in the elastomer as component (B) is in the range of from 1:99 to 45:55, the interlayer insulating film obtained by curing the resin composition has a tensile elongation of 15% or more at 25° C., and thus such a ratio is preferred. The ratio of the hard segment and the soft segment in the elastomer as component (B) is more preferably 1:99 to 44:56, further preferably 10:90 to 40:60. The ratio of the hard segment and the soft segment is preferably expressed in terms of a weight ratio or mass ratio. When the elastomer as component (B) is a commercially available product, with respect to the ratio of the hard segment and the soft segment in the component (B), reference can be made to the value shown in a catalogue of the product.

In the elastomer as component (B), the hard segment is a portion having a glass transition temperature (Tg) of 0 to less than 130° C., and the soft segment is a portion having a Tg of lower than 0° C., and the elastomer is preferably a block copolymer comprising the hard segment and the soft segment. The glass transition temperature Tg can be measured by differential scanning calorimetry (DSC).

Examples of the hard segments in the block copolymer include a methyl (meth)acrylate unit and a styrene unit. Examples of the soft segments include a n-butyl acrylate unit and a butadiene unit. In the present description, the term “(meth)acrylate” collectively refers to acrylate and methacrylate, and this applies to other similar expressions. The “(meth)acryl group” means an acryl group and a methacryl group.

The elastomer as component (B) is preferably a thermoplastic elastomer, and there can be mentioned a thermoplastic elastomer defined by JIS K6418, and examples of thermoplastic elastomers include a styrene thermoplastic elastomer (TPS), an olefin thermoplastic elastomer (TPO), a urethane thermoplastic elastomer (TPU), an ester thermoplastic elastomer (TPC), an amide thermoplastic elastomer (TPA), a thermoplastic rubber crosslinked material (TPV), and other thermoplastic elastomers (TPZ) having the composition or structure that is not included in the classifications for the above thermoplastic elastomers. Particularly, from the viewpoint of achieving excellent electrical properties when used in a high frequency region, the resin composition used in a semiconductor device of an FO-WLP type preferably contains a styrene thermoplastic elastomer. The styrene thermoplastic elastomer may be a styrene thermoplastic elastomer defined by JIS K6418, which is an at least three-block copolymer comprising styrene and a diene, in which two blocks (hard segment) at both ends are polystyrene and the inside block (one or a plurality of soft segments) comprises a polydiene or hydrogenated polydiene.

The elastomer as component (B) may be a rubbery copolymer, defined by JIS K6397, comprising carboxylated acrylonitrile having an end modified with a carboxyl group and butadiene (frequently referred to as XNBR or “carboxylated nitrile butadiene rubber”). In the case where the elastomer as component (B) contains an XNBR, when the resin composition contains the below-mentioned solvent as component (C), the XNBR is easily dissolved in the solvent as component (C), and the resultant resin composition has more excellent thixotropic properties, and, for example, in the case where the resin composition is applied to the semiconductor chip and the encapsulation material using a spin coater, a film having a substantially uniform thickness that has less unevenness can be formed. When the elastomer as component (B) is an XNBR, the ratio of the hard segment comprising a carboxylated acrylonitrile unit and the soft segment comprising butadiene can be determined from the amount of the carboxyl group contained in the component (B) in the resin composition. The amount of the carboxyl group contained in the component (B) can be measured using, for example, a nuclear magnetic resonance (NMR) apparatus.

With respect to the elastomer as component (B), examples of styrene thermoplastic elastomers include a styrene/butadiene/styrene block copolymer (SBS). The styrene/butadiene/styrene block copolymer (SBS) is a non-hydrogenated block copolymer. When the resin composition contains a styrene/butadiene/styrene block copolymer as the component (B), the flexibility or solubility in a solvent is improved, and the resin composition can be advantageously applied to the semiconductor chip and the encapsulation material using a spin coater. Further, even when the resin composition contains a styrene/butadiene/butylene/styrene copolymer (SBBS) which is a partially hydrogenated elastomer as the component (B), the resin composition can be similarly advantageously applied to the semiconductor chip and the encapsulation material. Further, the elastomer as component (B) may be a styrene/ethylene/butylene/styrene block copolymer (SEBS) obtained by completely hydrogenating a styrene/butadiene/styrene block copolymer. Further, the elastomer as component (B) may be a styrene/ethylene/ethylene/propylene/styrene block copolymer (SEEPS).

When the elastomer as component (B) is a styrene thermoplastic elastomer, the ratio of the hard segment comprising a styrene unit and the soft segment other than the styrene unit can be determined from, for example, the amount of the styrene contained in the component (B) in the resin composition. The amount of the styrene contained in the component (B) in the resin composition can be measured using, for example, nuclear magnetic resonance (NMR). Specifically, tetrachloroethane is used as a solvent, and the amount of the styrene can be calculated from the values obtained by determining an area value of a peak in the range of from 5.5 to 6.5 ppm, which is ascribed to styrene, and an area value of peaks in the other range.

Taking into consideration the tensile elongation of the interlayer insulating film obtained by curing the resin composition, and the uniformity of the thickness of a film obtained by applying the resin composition using, for example, a spin coater, and compatibility with the below-mentioned solvent as component (C) contained in the resin composition, the component (B) preferably has a number average molecular weight (Mn) of 40,000 to 600,000, more preferably 50,000 to 150,000, further preferably 60,000 to 120,000. The number average molecular weight (Mn) of the component (B) can be determined by the same method as mentioned above, for example, from a polystyrene converted value obtained by measurement of gel permeation chromatography (GPC).

With respect to the component (B), a commercially available product can be used. Examples of commercially available products of the component (B) include trade names “TR2827”, “TR2000”, and “TR2003”, manufactured by JSR Corporation; trade names “Tuftec (trademark) P1083”, “Tuftec (trademark) P1500”, “Tuftec (trademark) P5051”, and “Tuftec (trademark) H1221”, manufactured by Asahi Kasei Corporation; trade name “Nipol (trademark) 1072”, manufactured by Zeon Corporation; trade names “SEPTON (trademark) 4033”, and “SEPTON (trademark) 4044”, manufactured by Kuraray Co., Ltd.; and trade name “KRATON (trademark) G1652MU”, manufactured by KRATON.

It is preferred that the resin composition further comprises (C) a solvent. In the resin composition for the interlayer insulating film for a semiconductor device of an FO-WLP type, the solvent is frequently referred to as “component (C)” or “solvent as component (C)”. When the interlayer insulating film or the resin composition for the interlayer insulating film contains the solvent as component (C), the component (A) and the component (B) can be easily dissolved or dispersed in the solvent, and, for example, when the resultant resin composition is applied to the semiconductor chip and encapsulation material using a spin coater, a film having a substantially uniform thickness that has less unevenness can be formed. The solvent as component (C) is unlikely to remain in the film, so that a lowering of the dielectric properties can be suppressed. The solvent as component (C) is preferably an organic solvent. The organic solvent preferably contains at least one member selected from the group consisting of an aromatic solvent and a ketone solvent. The solvent as component (C) is preferably at least one member selected from the group consisting of toluene, xylene, acetone, methyl ethyl ketone, methyl isobutyl ketone, acetophenone, cyclohexanone, cyclohexane, dimethyl carbonate, methylcyclohexanone, and Y-butyrolactone. The solvents as component (C) may be used individually or in combination. With respect to the solvent as component (C), toluene or cyclohexanone can be used, and, of these, from the viewpoint of the toxicity, cyclohexanone is preferably used. The resin composition can be used in the form of a varnish that is obtained by dissolving or dispersing the component (A) and component (B) in the solvent as component (C). A varnish comprising the resin composition containing the components (A), (B), and (C) preferably has the below-mentioned first viscosity and second viscosity. Further, the varnish comprising the resin composition containing the components (A), (B), and (C) preferably has the below-mentioned thixotropy index TI.

With respect to the component (C), a commercially available product can be used. As a commercially available product of the component (C), for example, toluene (toluene concentration: 100% by mass; manufactured by Daishin Chemical Co., Ltd.), Anone (cyclohexanone) (cyclohexanone concentration: 90 to 100% by mass; manufactured by Daishin Chemical Co., Ltd.), or methyl ethyl ketone (MEK) (2-butanone) (2-butanone concentration: 90 to 100% by mass; manufactured by Daishin Chemical Co., Ltd.) can be used.

The resin composition can further contain (D) an additive. The additive (D) is frequently referred to as “component (D)” or “additive as component (D)”. The additive as component (D) contains at least one member selected from the group consisting of an organic peroxide, a coupling agent, an ion trapping agent, a leveling agent, an antioxidant, a viscosity modifier, and a flame retardant. When the resin composition contains an organic peroxide as the additive as component (D), the reactivity of the resin composition can be improved. When the resin composition contains a coupling agent as the additive as component (D), the adhesion of the semiconductor chip and encapsulation material to the resin composition applied thereto can be improved. The additive as component (D) preferably contains at least one member selected from the group consisting of an organic peroxide and a coupling agent. The additive as component (D) is more preferably an organic peroxide.

Taking the reactivity of the component (A) and component (B) into consideration, the additive as component (D) more preferably contains an organic peroxide for initiating a radical polymerization reaction. With respect to the organic peroxide as the additive as component (D), a commercially available product can be used. With respect to the commercially available product of the organic peroxide as the additive as component (D), for example, trade name “PERBUTYL (trademark) Z (tert-butyl peroxybenzoate)” or “PERCUMYL (trademark) D (bis(1-methyl-1-phenylethyl)=peroxide)”, manufactured by NOF Corporation, a peroxycarbonate, or the like can be used.

The coupling agent is a compound having two or more different functional groups per molecule, in which one of them is a functional group that undergoes chemical bonding to an inorganic material, and another one is a functional group that undergoes chemical bonding to an organic material. As examples of the coupling agents, there can be mentioned at least one member selected from the group consisting of a silane coupling agent, an aluminum coupling agent, and a titanium coupling agent, and a silane coupling agent may be used. The coupling agents may be used individually or in combination. Examples of functional groups of the silane coupling agent include an alkoxy group, a vinyl group, an epoxy group, a styryl group, a methacryl group, an acryl group, an amino group, an isocyanurate group, an ureido group, a mercapto group, a sulfide group, and an isocyanate group. With respect to the additive, a commercially available product may be used, and, when the additive is a silane coupling agent, for example, trade name “KBM503 (3-methacryloxypropyltrimethoxysilane)”, or “KBM 1003 (vinyltrimethoxysilane)”, Shin-Etsu Silicone manufactured by Shin-Etsu Chemical Co., Ltd., or trade name “Coatsil MP200 Silane”, manufactured by Momentive Performance Materials Inc., can be used.

The resin composition can further contain (E) a fluidity imparting agent. The fluidity imparting agent (E) is frequently referred to as “component (E)” or “fluidity imparting agent as component (E)”. The fluidity imparting agent indicates a compound having a function of imparting fluidity to the resin composition. In the present description, imparting fluidity indicates that the viscosity of the resin composition, as measured under, for example, the below-mentioned conditions, can be reduced to 1,000 mPa·s or less. With respect to the fluidity imparting agent as component (E), for example, there can be mentioned at least one compound selected from the group consisting of a compound having a butadiene skeleton having a 1,2-vinyl group, and a compound which has an isocyanuric ring structure and two allyl groups per molecule, and which is in a liquid state at 25° C. When the resin composition contains the component (E) as well as the components (A) and (B), the obtained resin composition can exhibit excellent fluidity.

The compound having a butadiene skeleton having a 1,2-vinyl group has a number average molecular weight of 1,000 to 10,000. When using the compound having such a number average molecular weight, excellent fluidity and excellent coefficient of thermal expansion can be obtained. The number average molecular weight (Mn) can be a value determined by the same method as mentioned above from a calibration curve obtained using standard polystyrene by a gel permeation chromatography (GPC) method.

Examples of the compounds having a butadiene skeleton having a 1,2-vinyl group include a butadiene polymer having a 1,2-vinyl group, a block copolymer comprising a butadiene block having a 1,2-vinyl group and a styrene block, and a styrene-butadiene copolymer having a 1,2-vinyl group.

Examples of the butadiene polymers having a 1,2-vinyl group include a 1,2-polybutadiene homopolymer, manufactured by Nippon Soda Co., Ltd. (trade name “B-3000”, “B-1000”), and a partially hydrogenated butadiene polymer, trade name “BI-3015”.

Examples of the styrene-butadiene block copolymers having a 1,2-vinyl structure include trade names “1,2-SBS-L42” and “1,2-H-SBS-L”, manufactured by Nippon Soda Co., Ltd.

Examples of the styrene-butadiene copolymers having a 1,2-vinyl group include trade names “Ricon 181” and “Ricon 100”, manufactured by CRAY VALLEY.

When the resin composition contains a compound which has an isocyanuric ring structure and two allyl groups per molecule and which is in a liquid state at 25° C., the resin composition can be reduced in melt viscosity, making it possible to improve the encapsulation properties for a wiring. Further, by virtue of having two allyl groups, extremely excellent low dielectric properties can be obtained. For example, when, instead of the compound which has an isocyanuric ring structure and two allyl groups per molecule and which is in a liquid state at 25° C., a compound having an isocyanuric ring structure and three allyl groups per molecule is used, satisfactorily low dielectric properties cannot be obtained. Detailed reasons for this are not clear, but it is presumed that when using the compound having three allyl groups, a three-dimensional crosslinked structure is formed, so that the dielectric properties become unsatisfactory. On the other hand, when using the compound which has an isocyanuric ring structure and two allyl groups per molecule and which is in a liquid state at 25° C., it is presumed that a linear crosslinked structure is formed and the dipole moment which is a yardstick for molecular polarization is reduced, so that low dielectric properties can be obtained. Further, complete elucidation has not been made, but it is presumed that the use of the compound having an isocyanuric ring structure improves the resin composition in heat resistance. Further, the use of the compound which is in a liquid state at 25° C. improves the encapsulation properties.

The compound which has an isocyanuric ring structure and two allyl groups per molecule, and which is in a liquid state at 25° C. preferably has a molecular weight of 300 to 400, further preferably 320 to 400. When the molecular weight of the compound is in the above range, excellent dielectric properties and excellent fluidity can be obtained.

The compound which has an isocyanuric ring structure and two allyl groups per molecule, and which is in a liquid state at 25° C. is preferably an isocyanuric acid (diallylated isocyanuric acid derivative) represented by the following formula (10):

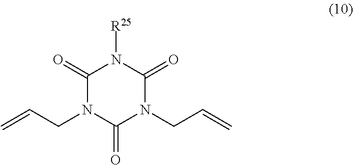

wherein R²⁵ represents a C₄-C₁₄ alkyl group.

In the formula (10), R²⁵ is preferably a C₈-C₁₄ alkyl group, especially preferably a C₁₀-C₁₂ alkyl group.

Examples of the isocyanuric acid (diallylated isocyanuric acid derivative) represented by the formula (10) above include trade name “L-DAIC”, manufactured by Shikoku Chemicals Corporation.

The resin composition for a semiconductor device of an FO-WLP type is required to comprise the component (A) and component (B), and may contain the component (C), and may contain a component other than the components (A), (B), and (C), and may not contain a component other than the components (A), (B), and (C). The resin composition may comprise only the component (A), component (B), and component (C).

The amount of the component (A) contained in the resin composition is preferably 10 to 75% by mass, more preferably 10 to 74% by mass, further preferably 10 to 73% by mass, still further preferably 15 to 72% by mass, especially preferably 20 to 72% by mass, based on the total mass of the components (A) and (B) (100% by mass). When the amount of the component (A) contained in the resin composition is 10 to 75% by mass, based on the total mass of the components (A) and (B), a cured product having a low permittivity and a low dielectric loss tangent can be obtained, so that an interlayer insulating film having excellent electrical properties suitable for the use in a high frequency region can be formed. Further, when the amount of the component (A) contained in the resin composition is 10 to 75% by mass, based on the total mass of the components (A) and (B) (100% by mass), the tensile elongation can be improved. Thus, even when forming an interlayer insulating film which is directly in contact with both the semiconductor chip and the encapsulation material having different coefficients of linear expansion, the obtained interlayer insulating film can suppress a removal of the two materials having different coefficients of linear expansion, and can suppress formation of a crack in the wiring contained in the rewiring layer and the like.

When the resin composition contains the solvent as component (C), the amount of the component (A) contained in the resin composition is preferably 3.0 to 30.0% by mass, more preferably 5.0 to 25.0% by mass, further preferably 6.0 to 20.0% by mass, based on the total mass of the components (A), (B), and (C) (100% by mass). When the amount of the component (A) contained in the resin composition is 3.0 to 30.0% by mass, based on the total mass of the components (A), (B), and (C) (100% by mass), a cured product having excellent tensile elongation and having a low permittivity and a low dielectric loss tangent can be obtained, and the cured product exhibits excellent electrical properties suitable for the use in a high frequency region. Further, when the amount of the component (A) contained in the resin composition is 3.0 to 30.0% by mass, based on the total mass of the components (A), (B), and (C) (100% by mass), for example, in the case where the resin composition is applied using a spin coater, a film having a substantially uniform thickness can be formed.

The amount of the component (B) contained in the resin composition is preferably 25 to 90% by mass, more preferably 26 to 90% by mass, further preferably 27 to 90% by mass, still further preferably 28 to 85% by mass, especially preferably 28 to 80% by mass, based on the total mass of the components (A) and (B) (100% by mass). When the resin composition does not contain the component (E), the amount of the component (B) contained in the resin composition may be 31 to 90% by mass, based on the total mass of the components (A) and (B) (100% by mass), and may be 35 to 90% by mass, may be 40 to 90% by mass, may be 45 to 85% by mass, and may be 50 to 80% by mass. When the amount of the component (B) contained in the resin composition is 25 to 90% by mass, based on the total mass of the components (A) and (B), or, in the case that the resin composition does not contain the component (E), when the amount of the component (B) contained is 31 to 90% by mass, based on the total mass of the components (A) and (B), excellent tensile elongation can be obtained by virtue of the component (B) in the resin composition and, even in the case forming an interlayer insulating film which is directly in contact with both the semiconductor chip and the encapsulation material having different coefficients of linear expansion, a removal of the two materials having different coefficients of linear expansion is suppressed, and formation of a crack in the wiring contained in the rewiring layer and the like can be suppressed. Further, when the amount of the component (B) contained in the resin composition is 25 to 90% by mass, based on the total mass of the components (A) and (B), or, in the case that the resin composition does not contain the component (E), when the amount of the component (B) contained in the resin composition is 31 to 90% by mass, based on the total mass of the components (A) and (B), a cured product having a low permittivity and a low dielectric loss tangent can be obtained, so that an interlayer insulating film having excellent electrical properties suitable for the use in a high frequency region can be formed. By using the resin composition in which the amount of the component (B) contained in the resin composition is 25 to 90% by mass, based on the total mass of the components (A) and (B) (100% by mass), there can be obtained a cured product having a tensile elongation of 15% or more at 25° C., having a low permittivity and a low dielectric loss tangent, and having excellent electrical properties when used in a high frequency region at 5 GHz or more, for example, 10 GHz.

The amount of the component (B) contained in the resin composition is preferably 2.0 to 40.0% by mass, more preferably 3.0 to 35.0% by mass, further preferably 3.0 to 30.0% by mass, based on the total mass of the components (A), (B), and (C) (100% by mass). When the amount of the component (B) contained in the resin composition is 2.0 to 40.0% by mass, based on the total mass of the components (A), (B), and (C) (100% by mass), a cured product having excellent tensile elongation and having a low permittivity and a low dielectric loss tangent can be obtained, and the cured product exhibits excellent electrical properties suitable for the use in a high frequency region. Further, when the amount of the component (B) contained in the resin composition is 2.0 to 40.0% by mass, based on the total mass of the components (A), (B), and (C) (100% by mass), for example, in the case where the resin composition is applied using a spin coater, a film having a substantially uniform thickness can be formed.

When the resin composition contains the component (E), the amount of the total of the component (B) and the component (E) contained in the resin composition is preferably 31 to 90% by mass, more preferably 35 to 90% by mass, further preferably 40 to 90% by mass, still further preferably 45 to 85% by mass, especially preferably 45 to 80% by mass, based on the total mass of the components (A), (B), and (E) (100% by mass). When the amount of the total of the component (B) and the component (E) contained in the resin composition is 31 to 90% by mass, based on the total mass of the components (A), (B), and (E), an interlayer insulating film having a tensile elongation of 15% or more can be obtained by virtue of the components (B) and (E) in the resin composition, and, even when forming an interlayer insulating film which is directly in contact with both the semiconductor chip and the encapsulation material having different coefficients of linear expansion, a removal of the two materials having different coefficients of linear expansion is suppressed, and formation of a crack in the wiring contained in the rewiring layer and the like can be suppressed. Further, when the amount of the total of the component (B) and the component (E) contained in the resin composition is 31 to 90% by mass, based on the total mass of the components (A), (B), and (E), a cured product having a low permittivity and a low dielectric loss tangent can be obtained by virtue of the component (E) in the resin composition even in the case where the amount of the component (B) is small, so that an interlayer insulating film having excellent electrical properties suitable for the use in a high frequency region can be formed. By using the resin composition in which the amount of the total of the component (B) and the component (E) contained in the resin composition is 31 to 90% by mass, based on the total mass of the components (A), (B), and (E) (100% by mass), there can be obtained a cured product having a tensile elongation of 15% or more at 25° C., having a low permittivity and a low dielectric loss tangent, and having excellent electrical properties when used in a high frequency region at 5 GHz or more, for example, 10 GHz.

The amount of the component (C) contained in the resin composition is preferably 30 to 95% by mass, more preferably 40 to 92% by mass, further preferably 50 to 91% by mass, based on the total mass of the components (A), (B), and (C) (100% by mass). When the amount of the component (C) contained is in the range of from 30 to 95% by mass, based on the total mass of the components (A), (B), and (C) (100% by mass), the component (A) and component (B) can be easily dissolved or dispersed in the component (C), and, for example, in the case where the resin composition is applied to a semiconductor substrate using a spin coater, a film having a substantially uniform thickness that has less unevenness can be formed, so that a cured product which has suppressed warpage of the semiconductor chip can be obtained. The resin composition can be used in the form of a varnish that is obtained by dissolving or dispersing the component (A) and component (B) in the solvent as component (C), but the solvent has volatilized in a cured product of the resin composition, and the cured product substantially does not contain the solvent. The expression that the cured product “substantially does not contain” the solvent means that the solvent may be present in the cured product in a very small amount (1% by mass or less). Even when the resin composition contains the component (E), the amount of the component (C) contained may be 30 to 95% by mass, based on the total mass of the components (A), (B), and (C) (100% by mass).

When the resin composition contains the additive (D), the amount of the additive as component (D) contained in the resin composition may be 10.0% by mass or less, based on the mass of the resin composition (100% by mass), and may be 8.0% by mass or less, and may be 5.0% by mass or less. The amount of the additive as component (D) contained in the resin composition may be 0.10% by mass or more. Even when the resin composition contains the component (E), the amount of the additive as component (D) may be 10.0% by mass or less, based on the mass of the resin composition (100% by mass).

When the resin composition contains the fluidity imparting agent (E) and the amount of the total of the component (B) and the component (E) contained in the resin composition satisfies 31 to 90% by mass, based on the total mass of the components (A), (B), and (E) (100% by mass), the amount of the fluidity imparting agent as component (E) contained in the resin composition may be 10.0% by mass or less, based on the mass of the resin composition (100% by mass), and may be 9.0% by mass or less, and may be 8.0% by mass or less. The amount of the fluidity imparting agent as component (E) contained in the resin composition may be 0.10% by mass or more.

When the resin composition for a semiconductor device of an FO-WLP type contains the components (A), (B), and (C), the resin composition preferably has a first viscosity in the range of from 300 to 4,000 mPa·s, as measured at 25° C. and at 10 rpm using a rotational viscometer. When the first viscosity of the resin composition is in the range of from 300 to 4,000 mPa·s, for example, even in the case where the resin composition is applied using a spin coater so as to be in contact with both the semiconductor chip and the encapsulation material, a film having a substantially uniform thickness that has less unevenness can be formed, so that warpage of the semiconductor chip caused during curing of the resin composition can be suppressed. The resin composition more preferably has a first viscosity of 320 to 4,000 mPa·s, further preferably 330 to 2,000 mPa·s. When the resin composition contains the fluidity imparting agent as component (E), the resin composition containing the fluidity imparting agent as component (E) preferably has a first viscosity in the range of from 300 to 1,000 mPa·s, more preferably in the range of from 310 to 900 mPa·s, further preferably in the range of from 320 to 800 mPa·s, especially preferably in the range of from 330 to 600 mPa·s. In the present description, a viscosity can be measured using, as the rotational viscometer, for example, a TVE type viscometer (cone rotor: 1° 34′×R²⁴; manufactured by Toki Sangyo Co., Ltd.).

When the resin composition for a semiconductor device of an FO-WLP type contains the components (A), (B), and (C), the resin composition preferably has a second viscosity in the range of from 200 to 4,200 mPa·s, as measured at 25° C. and at 1 rpm using a rotational viscometer. When the second viscosity of the resin composition is in the range of from 200 to 4,200 mPa·s, for example, even in the case where the resin composition is applied using a spin coater so as to be in contact with both the semiconductor chip and the encapsulation material, a film having a substantially uniform thickness that has less unevenness can be formed, so that warpage of the semiconductor chip caused during curing of the resin composition can be suppressed. The resin composition more preferably has a second viscosity in the range of from 210 to 4,000 mPa·s, further preferably in the range of from 220 to 4,000 mPa·s, especially preferably in the range of from 230 to 3,500 mPa·s. When the resin composition contains the fluidity imparting agent as component (E), the resin composition containing the fluidity imparting agent as component (E) preferably has a second viscosity in the range of from 200 to 1,100 mPa·s, more preferably in the range of from 210 to 1,000 mPa·s, further preferably in the range of from 220 to 900 mPa·s, especially preferably in the range of from 230 to 600 mPa·s.

It is preferred that the resin composition containing the components (A), (B), and (C) has a thixotropy index TI in the range of from 0.5 to 3.0, in terms of the ratio of the second viscosity to the first viscosity, and thus has thixotropic properties close to those of a Newtonian fluid. The term “Newtonian fluid” means a fluid having properties such that the shear stress of the fluid is proportional to the shear rate. When the thixotropy index TI of the resin composition is in the range of from 0.5 to 3.0, in terms of the ratio of the second viscosity to the first viscosity, for example, in the case where the resin composition is applied to a semiconductor substrate using a spin coater, a film having a substantially uniform thickness that has less unevenness can be formed, so that warpage of the semiconductor substrate caused during curing of the resin composition can be suppressed. The resin composition more preferably has a thixotropy index in the range of from 0.6 to 1.2, further preferably in the range of from 0.70 to 1.19, still further preferably in the range of from 0.80 to 1.19, especially preferably in the range of from 0.90 to 1.10, further especially preferably in the range of from 1.00 to 1.10, in terms of the ratio of the second viscosity to the first viscosity. When the resin composition contains the fluidity imparting agent as component (E), the resin composition containing the fluidity imparting agent as component (E) preferably has a thixotropy index TI in the range of from 0.5 to 3.0, in terms of the ratio of the second viscosity to the first viscosity.

With respect to the resin composition constituting an interlayer insulating film for a semiconductor device of an FO-WLP type, a film which is formed from a cured product obtained by curing the resin composition preferably has a specific permittivity (ε) of 4.0 or less, more preferably 3.5 or less, further preferably 3.0 or less, still further preferably 2.8 or less, especially preferably 2.7 or less. With respect to the lower limit of the specific permittivity (ε) of the film which is formed from a cured product obtained by curing the resin composition constituting an interlayer insulating film, there is no particular limitation, but the lower limit of the specific permittivity may be 1.0 or more, and may be 1.5 or more. Further, the film which is formed from the resin composition constituting an interlayer insulating film preferably has a dielectric loss tangent (tan δ) of 0.010 or less, more preferably 0.005 or less, further preferably 0.003 or less. With respect to the lower limit of the dielectric loss tangent (tan δ) of the film which is formed from the resin composition constituting an interlayer insulating film, there is no particular limitation, but the lower limit of the dielectric loss tangent may be 0.0001 or more, and may be 0.0005 or more. When the film which is formed from the resin composition constituting an interlayer insulating film for a semiconductor device of an FO-WLP type has a specific permittivity of 4.0 or less and a dielectric loss tangent (tan δ) of 0.010 or less, the film has a low permittivity and a low dielectric loss tangent and exhibits excellent electrical properties when used in a high frequency region. For example, there can be obtained a film which exhibits excellent electrical properties when a semiconductor device having such a film is used in a high frequency region for, for example, fifth-generation mobile communications system “5G”, which is expected to be further increased in the capacity and transmission speed. For example, a semiconductor device which is expected to be used in a high frequency region for, for example, “5G” may have a specific permittivity (e) in the range of from 1.0 to 4.0, and may have a specific permittivity (ε) in the range of from 1.5 to 3.0, as measured at a dielectric resonance frequency of 10 GHz by a dielectric resonator method (SPDR method). Further, the semiconductor device may have a dielectric loss tangent (tan δ) in the range of from 0.0001 to 0.010, and may have a dielectric loss tangent (tan δ) in the range of from 0.0005 to 0.005. The semiconductor device may have a specific permittivity (ε) of 1.0 to 4.0, as measured at a dielectric resonance frequency of 10 GHz by a dielectric resonator method (SPDR method), so that, for example, the semiconductor device can be used even in the frequency region lower than “5G”, and the semiconductor device may have a specific permittivity (E) in the range of from 1.5 to 3.0. Further, the semiconductor device may have a dielectric loss tangent (tan δ) in the range of from 0.0001 to 0.010, and may have a dielectric loss tangent (tan δ) in the range of from 0.0005 to 0.005.

The resin composition contains the component (A) and component (B), and therefore, with respect to the resin composition applied so as to be in contact with both the semiconductor chip and the encapsulation material, the semiconductor chip and the encapsulation material have different coefficients of linear expansion, and the interlayer insulating film formed from the resin composition absorbs expansion and shrinkage of the semiconductor chip and the encapsulation material having different coefficients of linear expansion due to thermal cycling that repeats a temperature change from ordinary room temperature which is a relatively low temperature to a relatively high temperature when the semiconductor device is operating, so that a removal of the semiconductor chip and the encapsulation material is suppressed, and formation of a crack in the wiring contained in the rewiring layer and the like can be suppressed.

With respect to the film sample obtained by curing the resin composition so as to have a width of 15 mm, a length of 200 mm, and a thickness of 100 μm, the film sample preferably has a coefficient of linear expansion of a 200 ppm/K or less at 50 to 60° C. (323 to 333 K) in the temperature range of from room temperature (25±5° C.) to 230° C., more preferably 180 ppm/K or less, further preferably 150 ppm/K or less, and the coefficient of linear expansion of the film sample may be 10 ppm/K or more, may be 20 ppm/K or more, and may be 30 ppm/K or more. The resin composition comprises the components (A) and (B), and may contain the component (E). When the cured product in a film form obtained by curing the resin composition has a coefficient of linear expansion of 200 ppm/K or less, the interlayer insulating film formed from the resin composition absorbs expansion and shrinkage of the semiconductor chip and the encapsulation material due to thermal cycling, so that a removal of the semiconductor chip and the encapsulation material is suppressed, and formation of a crack in the wiring contained in the rewiring layer and the like can be suppressed.

The resin composition can be used in a semiconductor device of an FO-WLP type, and can be used around the wiring of a semiconductor device. It is preferred that the resin composition does not contain an inorganic filler, such as silica. The interlayer insulating film formed by curing the resin composition is irradiated with a laser for perforation processing in the subsequent step to form a via hole for wiring. In this processing, when the interlayer insulating film contains an inorganic filler, such as silica, it is likely that the laser treatment cannot well process the silica portion, making it difficult to advantageously achieve the subsequent copper plating for a via hole. Therefore, it is preferred that the resin composition does not contain an inorganic filler, such as silica. The resin composition which does not contain an inorganic filler, such as silica, means that an inorganic filler is intentionally not added to the resin composition, and the resin composition may contain an inorganic filler in an amount in the range of from 0.0001 to 0.01% by mass, based on the mass of the resin composition (100% by mass), and may contain an inorganic filler in an amount of 0% by mass or may contain no inorganic filler.

### Method for Producing the Resin Composition

The resin composition can be produced by mixing the component (A) and component (B) and optionally the component (C). The resin composition may be produced by mixing the component (A) and component (B) and optionally the component (C) and optionally the additive as component (D) and/or fluidity imparting agent as component (E). Addition of a filler, such as silicon dioxide or aluminum oxide, may cause the resin composition to have poor application properties, and therefore is not preferred. It is preferred that the resin composition does not contain a silicon dioxide or aluminum oxide powder. With respect to the method for producing the resin composition, there is no particular limitation. The resin composition can be produced by mixing raw materials for the components by means of a mixing machine, such as a Raikai mixer, a pot mill, a three-roll mill, a hybrid mixer, a rotary mixer, or a twin-screw mixer. The components of the resin composition may be mixed in such a way that all the components are mixed at the same time, or in such a way that part of the components are first mixed with each other and then the remaining components are mixed into the mixture. Further, the apparatuses appropriately selected may be used in combination in the production of the resin composition.

The cured product obtained by curing the resin composition can be used in a semiconductor device of an FO-WLP type, and can be used around the wiring of a semiconductor device. The cured product can be used as an interlayer insulating film for a semiconductor device of an FO-WLP type, and the cured product has a tensile elongation of 15% or more at 25° C., and may have a tensile elongation of 500% or less. In the case where the cured product obtained by curing the resin composition is used as an interlayer insulating film for a semiconductor device of an FO-WLP type, when the interlayer insulating film of the rewiring layer of the semiconductor device has a tensile elongation of 15% or more at 25° C., it is possible to suppress a removal of the semiconductor chip and the encapsulation material having different coefficients of linear expansion due to expansion and shrinkage caused by thermal cycling that repeats a temperature change from ordinary room temperature which is a relatively low temperature to a relatively high temperature when the semiconductor device is operating, and formation of a crack in the wiring contained in the rewiring layer and the like can be suppressed.

With respect to the cured product obtained by curing the resin composition, the cured product preferably has a specific permittivity (e) of 4.0 or less, more preferably 3.5 or less, further preferably 3.0 or less, still further preferably 2.8 or less, especially preferably 2.7 or less. The cured product obtained by curing the resin composition may have a dielectric loss tangent (tan δ) of 0.015 or less, and the dielectric loss tangent may be 0.014 or less, may be 0.013 or less, and may be 0.012 or less, preferably 0.010 or less. The cured product having a low permittivity and a low dielectric loss tangent exhibits excellent electrical properties when used in a high frequency region, and therefore can be used in an electronic part, a semiconductor device, and the like which are used in a high frequency region. Further, when the resin composition is applied to a semiconductor substrate using, for example, a spin coater, the composition is satisfactorily cured, and a semiconductor device having such a cured product can be used in a high frequency region for, for example, fifth-generation mobile communications system “5G”, which is expected to be further increased in the capacity and transmission speed.

### Method for Producing the Semiconductor Device

A method for producing the semiconductor device is described below. Hereinafter, the semiconductor device means a semiconductor device of an FO-WLP type unless otherwise specified. The semiconductor device comprises an interlayer insulating film obtained by curing the above-described resin composition or a resin composition for a semiconductor device.

A plurality of semiconductor chips are disposed at predetermined intervals on a support, and a molding resin as an encapsulation material is applied onto the semiconductor chips to encapsulate the semiconductor chips with the molding resin. The semiconductor chips may be bonded to the support. The semiconductor chips are encapsulated with a molding resin, and then the support is removed, so that the semiconductor chips and the encapsulation material having the molding resin cured are adjacent to each other and present on substantially the same plane. Then, a film of a conductive material is formed on the semiconductor chips at a predetermined position, by, for example, a vacuum deposition method or a sputtering method, and then patterned by, for example, a photolithography method, forming a plurality of terminals on the semiconductor chips at predetermined positions. A wiring is formed so as to connect the terminals formed on the semiconductor chips to an external terminal, and the resin composition is applied to the portion on which the wiring is not formed, and the resin composition is cured by heating, forming an interlayer insulating film. Each of the interlayer insulating film and the wiring may have a plurality of layers stacked. A second support is bonded to the back side opposite to the semiconductor chips and the encapsulation material which are present on substantially the same plane, from which the support has been removed. The semiconductor chips may be encapsulated with a molding resin.

With respect to the formation of the interlayer insulating film, for example, the resin composition is applied dropwise onto the semiconductor chips and the encapsulation material which are present on substantially the same plane, and the second support is spun on the vertical axis using a spin coater to apply the resin composition in a liquid state onto the semiconductor chips and the encapsulation material which are present on the same plane, and the resin composition in a liquid state is cured to form an interlayer insulating film. Specifically, the resin composition is applied dropwise onto the semiconductor chips and encapsulation material including the terminal, and the second support which supports the semiconductor chips and encapsulation material is spun on the vertical axis using a spin coater to apply the resin composition in a liquid state to the semiconductor chips and encapsulation material, and the resin composition in a liquid state is cured to form an interlayer insulating film.

In the application of the resin composition for forming an interlayer insulating film, the rotational speed of the spin coater is preferably 1,000 to 3,000 rpm, and the time of rotation is preferably 5 to 30 seconds. When the rotational speed of the spin coater and the time of rotation are in the above-mentioned respective ranges, the resin composition can be applied onto the semiconductor chips and the encapsulation material so as to have a substantially uniform thickness, and, after cured, an interlayer insulating film having a substantially uniform thickness as desired can be formed, so that a removal of the semiconductor chips and the encapsulation material during being cured can be easily suppressed. A method may be employed in which the resin composition is applied onto the semiconductor chips and encapsulation material and cured to form an interlayer insulating film, followed by cutting using a dicing saw or the like into pieces of the encapsulation material and interlayer insulating film for each semiconductor chip.

The interlayer insulating film can be formed using a resin composition comprising the above-mentioned components (A) and (B) and optionally the component (C). The interlayer insulating film can be formed using a resin composition comprising the above-mentioned components (A) and (B) and optionally the component (C) and optionally an additive as component (D) and/or a fluidity imparting agent as component (E). The interlayer insulating film may have a plurality of interlayer insulating films stacked.

In the application of the resin composition to the semiconductor chips and the encapsulation material using a spin coater, the above-mentioned resin composition preferably has a first viscosity of 300 to 4,000 mPa·s, more preferably 400 to 4,000 mPa·s, further preferably 500 to 2,000 mPa·s, as measured at 25° C. and at 10 rpm using a rotational viscometer. In the application of the above-mentioned resin composition to the semiconductor chips and the encapsulation material using a spin coater, when the first viscosity of the resin composition is in the above range, a film having a substantially uniform thickness that has less unevenness can be formed, so that a removal of the semiconductor chips and the encapsulation material can be suppressed.

In the application of the resin composition to the semiconductor chips and the encapsulation material using a spin coater, the above-mentioned resin composition preferably has a second viscosity in the range of from 200 to 4,200 mPa·s, more preferably in the range of from 210 to 4,000 mPa·s, further preferably in the range of from 220 to 4,000 mPa·s, still further preferably in the range of from 230 to 3,500 mPa·s, as measured at 25° C. and at 1 rpm using a rotational viscometer. In the application of the above-mentioned resin composition using a spin coater to the semiconductor chips and the encapsulation material, when the second viscosity of the resin composition is in the above range, a film having a substantially uniform thickness that has less unevenness can be formed, so that a removal of the semiconductor chips and the encapsulation material can be further suppressed.

In the application of the resin composition to the semiconductor chips and the encapsulation material using a spin coater, the above-mentioned resin composition preferably has a thixotropy index TI in the range of from 0.8 to 1.2, in terms of the ratio of the second viscosity to the first viscosity, and may have a thixotropy index TI in the range of from 0.9 to 1.1, and may have a thixotropy index TI in the range of from 1.0 to 1.1. In the application of the above-mentioned resin composition to the semiconductor chips and the encapsulation material using a spin coater, when the ratio of the second viscosity to the first viscosity of the resin composition is in the above range, a film having a substantially uniform thickness that has less unevenness can be formed, so that a removal of the semiconductor chips and the encapsulation material can be further suppressed.

When the interlayer insulating film has stacked a plurality of films, such as a first interlayer insulating film and a second interlayer insulating film, each film preferably has a thickness in the range of from 3 to 20 μm, and may have a thickness in the range of from 4 to 18 μm, and may have a thickness in the range of from 5 to 17 μm. With respect to the interlayer insulating film, when the thickness of each layer is in the range of from 3 to 20 μm, even the interlayer insulating film having a plurality of films stacked can meet the need for reduction of the size and thickness of a semiconductor device.

In the method for producing a semiconductor device, the resin composition is applied and then dried, and cured, and then subjected to laser direct patterning using, for example, a laser direct patterning apparatus (manufactured by Mitsubishi Electric Corporation), forming a first interlayer insulating film (dielectric film) having opened the surface portion of the electrode.

Then, on the substantially entire surface of the first interlayer insulating film formed on the semiconductor chips and the encapsulation material which are present on substantially the same plane, a seed layer for forming a wiring is formed by a vapor deposition method, a sputtering method, a chemical vapor deposition (CVD) method, an electroless plating method, or the like. The seed layer contains copper, and may be a seed layer that contains copper oxide, an alloy of copper and chromium, copper, tantalum, cobalt, titanium, or an alloy thereof. The seed layer may have a stacked structure in which a plurality of layers are stacked on one another. On the seed layer, a resist with a predetermined pattern is formed by, for example, a photolithography method, and, using the resultant resist film as a mask, a wiring with the predetermined pattern is formed by electroplating or electroless plating. The wiring is formed and then the resist film is removed, and the seed layer remaining in the region in which the wiring is not formed is removed by etching or the like. With respect to the thickness of the wiring, there is no particular limitation, but the thickness of the wiring may be 0.1 μm or more, and may be 15 μm or less, may be 12 μm or less, and may be 10 μm or less.

Then, the resin composition is applied onto the wiring using a spin coater so that the surface height of the applied composition becomes substantially uniform, forming a second interlayer insulating film. In the formation of the second interlayer insulating film, like the formation of the first interlayer insulating film, the resin composition comprising the above-mentioned components (A), (B), and (C) can be used, and can be applied onto the wiring using a spin coater having the same rotational speed and time of rotation as those for the first interlayer insulating film. The resin composition is applied and then dried, and cured, and then subjected to laser direct patterning using, for example, a laser direct patterning apparatus (manufactured by Mitsubishi Electric Corporation), forming a second interlayer insulating film having opened the surface portion of the wiring corresponding to the portion on which the below-mentioned external terminal is disposed. With respect to the second interlayer insulating film, the surface portion of the electrode can be opened by exposure and development.

The forming a first interlayer insulating film, forming a wiring, and forming a second interlayer insulating film are collectively referred to also as “forming a rewiring layer”.

Then, an external terminal, such as a solder ball, is formed in the opening portion of the rewiring layer by a solder ball mounting method, a solder plating method, a soldering paste method, a soldering paste dispensing method, a solder vapor deposition method, or the like, forming a semiconductor device of an FO-WLP type. In the thus formed semiconductor device of an FO-WLP type, the interlayer insulating film comprising the first interlayer insulating film and the second interlayer insulating film is formed using the resin composition comprising the above-mentioned components (A), (B), and (C), and therefore the interlayer insulating film has a tensile elongation as large as 15% or more and suppresses a removal of the semiconductor chips and the encapsulation material, and the interlayer insulating film has a low permittivity and a low dielectric loss tangent, and the semiconductor device exhibits excellent electrical properties even when the semiconductor device is used in a high frequency region for, for example, fifth-generation mobile communications system “5G”, which is expected to be further increased in the capacity and transmission speed.

The interlayer insulating film and resin composition of an embodiment of the present invention and a semiconductor device comprising an interlayer insulating film obtained by curing the resin composition can be used in electronic parts for electronic devices, such as a mobile phone, a smartphone, a laptop computer, a tablet terminal, and a camera module.

### EXAMPLES

Hereinbelow, the present invention will be described in more detail with reference to the following Examples, which should not be construed as limiting the scope of the present invention. In the following Examples and Comparative Example, the figures indicating the formulation of the components contained in the resin composition are expressed in terms of the amount ((%) by mass), based on the mass of the resin composition (100% by mass), unless otherwise specified. When the resin composition contains only the components (A), (B), and (C) and does not contain an additive and the like, the mass of the resin composition means the total mass of the components (A), (B), and (C).

### Component (A): Thermosetting Resin Having an Unsaturated Double Bond at the End Thereof (Polyphenylene Ether)

A1: OPE 2st 1200 (modified polyphenylene ether resin having a vinyl group at both ends, and being represented by the formula (6) (reaction product of 2,2′,3,3′,5,5′-hexamethylbiphenyl-4,4′-diol/2,6-dimethylphenol condensation product and chloromethylstyrene); number average molecular weight (Mn): 1,200) (manufactured by Mitsubishi Gas Chemical Company, Inc.).
A2: OPE 2st 2200 (modified polyphenylene ether resin having a vinyl group at both ends, and being represented by the formula (6) (reaction product of 2,2′,3,3′,5,5′-hexamethylbiphenyl-4,4′-diol/2,6-dimethylphenol condensation product and chloromethylstyrene); number average molecular weight (Mn): 2,200) (manufactured by Mitsubishi Gas Chemical Company, Inc.).
A3: NORYL SA9000 (modified polyphenylene ether resin having a methacryloyl group at both ends, and being represented by the formula (5), which has at the end a group represented by the formula (3); number average molecular weight (Mn): 1,850 to 1,950) (manufactured by SABIC Innovative Plastics Japan LLC.). Component (B): Elastomer
B1: Styrene/butadiene/styrene block copolymer (SBS) TR2827; hard segment (styrene)/soft segment (butadiene) ratio: 24/76(%); number average molecular weight (Mn): 130,000 (manufactured by JSR Corporation).
B2: Styrene/butadiene/styrene block copolymer (SBS) TR2003; hard segment (styrene)/soft segment (butadiene) ratio: 43/57(%); number average molecular weight (Mn): 100,000 (manufactured by JSR Corporation).
B3: Styrene/butadiene/butylene/styrene block copolymer (SBBS), Tuftec (trademark) P1083; hard segment (styrene)/soft segment (ethylene-butadiene) ratio: 20/80(%); number average molecular weight (Mn): 59,000 (manufactured by Asahi Kasei Corporation).
B4: Styrene/butadiene/butylene/styrene block copolymer (SBBS), Tuftec (trademark) P1500; hard segment (styrene)/soft segment (ethylene-butadiene) ratio: 30/70(%); number average molecular weight (Mn): 50,000 (manufactured by Asahi Kasei Corporation).
B5: Carboxylated nitrile butadiene rubber (XNBR) Nipol (trademark) 1072, which has been modified with a carboxyl; hard segment (carboxyl)/soft segment (nitrile butadiene) ratio: 8/92; number average molecular weight (Mn): 500,000 (manufactured by Zeon Corporation)
B6: Styrene/ethylene/ethylene/propylene/styrene block copolymer (SEEPS) SEPTON (registered trademark) 4033; hard segment (styrene)/soft segment (ethylene-ethylene-propylene) ratio: 30/70(%); number average molecular weight (Mn): 100,000 (manufactured by Kuraray Co., Ltd.).
B7: Styrene/ethylene/butadiene/styrene block copolymer (SEBS), Tuftec (trademark) H1221; hard segment (styrene)/soft segment (ethylene-butadiene) ratio: 12/88(%); number average molecular weight (Mn): 170,000 (manufactured by Asahi Kasei Corporation).
B8: Styrene/ethylene/butadiene/styrene block copolymer (SEBS), KRATON (trademark) G1652; hard segment (styrene)/soft segment (ethylene-butadiene) ratio: 30/70(%); number average molecular weight (Mn): 200,000 (manufactured by KRATON).

### Component (C): Solvent

C1: Toluene (manufactured by Daishin Chemical Co., Ltd.); boiling point: 110.6° C.
C2: Anone (cyclohexanone, manufactured by Daishin Chemical Co., Ltd.); boiling point: 155.65° C.
C3: Methyl ethyl ketone (MEK) (2-butanone) (2-butanone concentration: 90 to 100% by mass; manufactured by Daishin Chemical Co., Ltd.); boiling point: 79.64° C. Component (D): Additive (organic peroxide)
D1: PERBUTYL (registered trademark) Z (manufactured by NOF Corporation)

### Component (E): Fluidity Imparting Agent

E1: Butadiene resin having a 1,2-vinyl structure B-1000; 1,2-vinyl structure: 85%; number average molecular weight (Mn): 1,200 (manufactured by Nippon Soda Co., Ltd.).
E2: Styrene-butadiene block copolymer having a 1,2-vinyl structure 1,2-SBS-L42; 1,2-vinyl structure: 90%; hard segment (styrene)/soft segment (butadiene) ratio: 20:80; number average molecular weight (Mn): 4,300 (manufactured by Nippon Soda Co., Ltd.).
E3: Isocyanuric acid (diallylated isocyanuric acid derivative) L-DAIC (manufactured by Shikoku Chemicals Corporation).

### Examples 1 to 17 and Comparative Example 1

The component (A), component (B), and component (C) and optionally an additive as component (D) (organic peroxide) were mixed and dissolved in a state at a constant temperature of 70° C. using a temperature-controlled water bath (SB-35, manufactured by Tokyo Rikakikai Co., Ltd.) and using a stirrer (SSR-112, manufactured by AGC Techno Glass Co., Ltd.), producing resin compositions in the Examples and Comparative Example. In each of Examples 1 to 13 and Comparative Example 1, the resin composition does not contain the component (E). In each of Examples 14 to 17, the resin composition contains the component (E). In Tables 1, 2, and 3, the symbol “-” indicates that the corresponding component is not contained in the resin composition. Further, in Tables 1, 2, and 3, the figures with no unit shown in the items mean those in terms of “% by mass”. Further, in Tables 1, 2, and 3, “H/S Ratio” indicates a hard segment/soft segment ratio.

### Evaluation of the Resin Composition and a Semiconductor Device Comprising an Interlayer Insulating Film

With respect to each of the resin compositions in the Examples and Comparative Example, an interlayer insulating film obtained by curing the resin composition, and a semiconductor device comprising the interlayer insulating film, the following evaluations were conducted. The results were shown in Table 1, 2, or 3.

### Solubility

With respect to each of the resin compositions, when the resin composition contains the component (A), component (B), and component (E), the solubility of the component (E) in the solvent as component (C) at 70° C. was visually evaluated. When containing the component (A), component (B), and component (E), a resin composition such that the component (E) was visually found to have been dissolved in the solvent as component (C) was rated “G (good)”, and a resin composition such that the component (E) was visually found not to be dissolved in the solvent as component (C) was rated “N (not-good)”.

### Viscosity (First Viscosity, Second Viscosity, and Thixotropy Index (TI))

With respect to each of the resin compositions, using a TVE type viscometer (cone rotor: 1° 34′×R²⁴; manufactured by Toki Sangyo Co., Ltd.), a first viscosity at 25° C. and at 10 rpm and a second viscosity at 25° C. and at 1 rpm were measured, and a thixotropy index TI (viscosity at 1 rpm/viscosity at 10 rpm), in terms of the ratio of the second viscosity to the first viscosity, was determined.

### Formation of an Interlayer Insulating Film

Using each of the resin compositions in the Examples and Comparative Example, a film which constitutes an interlayer insulating film was formed, and subjected to heat treatment under the conditions shown below to cure the film formed from the resin composition, and, with respect to the resultant cured product, the following evaluations were conducted.

### Thickness of the Interlayer Insulating Film

The resin compositions in the Examples and Comparative Example were individually applied by spin coating to a silicon wafer having a diameter of 150 mm and a thickness of 0.525 mm as a semiconductor substrate used for a semiconductor chip using a spin coater (MS-A200, manufactured by Mikasa Co., Ltd.). In the spin coating, the spin coater was operated at 1,000 rpm for 5 seconds and then at 2,000 rpm for 30 seconds to apply the resin composition to the surface of the silicon wafer by spin coating, forming a film.

Further, the resin compositions in the Examples and Comparative Example were individually applied by spin coating to a silicon wafer having a diameter of 150 mm and a thickness of 0.525 mm as a semiconductor substrate used for a semiconductor chip using a spin coater (MS-A200, manufactured by Mikasa Co., Ltd.). In the spin coating, the spin coater was operated at 1,000 rpm for 5 seconds and then at 3,000 rpm for 30 seconds to apply the resin composition to the surface of the silicon wafer by spin coating, forming a film.

Subsequently, the silicon wafer having a thin film of the resin composition was subjected to heat pretreatment (drying) in a nitrogen gas atmosphere at 130° C. for 10 minutes, and heated to obtain a specimen having the dried film of the resin composition. Then, the obtained specimen was subjected to heat treatment (curing) in a nitrogen gas atmosphere at 200° C. for 60 minutes, obtaining a specimen having the cured film of the resin composition. A thickness of the film of the resin composition was measured by a stylus profiling system (Surfcom 300B, manufactured by Tokyo Seimitsu Co., Ltd.). The interlayer insulating film can have a thickness of about 5 to 30 μm. The thickness of the interlayer insulating film may be 5 μm or more, and may be 10 μm or more. Further, the thickness of the interlayer insulating film may be 30 μm or less, and may be 20 μm or less.

### Specific Permittivity (ε) and Dielectric Loss Tangent (Tan δ)

A specimen for measurement was produced as follows.

The resin compositions in the Examples and Comparative Example were individually applied to a support made of polyethylene terephthalate (PET), and subjected to heat pretreatment (drying) in a nitrogen gas atmosphere at 130° C. for 10 minutes, and heated to dry the resin composition, and subjected to treatment (curing) in a nitrogen gas atmosphere at 200° C. for 60 minutes, obtaining a film formed from the resin composition (cured product) having a thickness of 30 μm.

A specific permittivity (e) and a dielectric loss tangent (tan δ) of a specimen for measurement were measured by a dielectric resonator method (SPDR method) at a dielectric resonance frequency of 10 GHz, which is needed for satisfying the high-frequency induction properties for, for example, “5G”. The cured product of the resin composition preferably has a specific permittivity (e) of 4.0 or less, more preferably 3.5 or less, especially preferably 3.0 or less. With respect to the lower limit of the specific permittivity (ε), there is no particular limitation, but, for example, the lower limit may be 1.0 or more, and may be 1.5 or more. The cured product of the resin composition preferably has a dielectric loss tangent (tan δ) of 0.010 or less, more preferably 0.005 or less, especially preferably 0.003 or less. With respect to the lower limit of the dielectric loss tangent, there is no particular limitation, but, for example, the lower limit may be 0.0001 or more, and may be 0.0005 or more.

The cured product of the resin composition may have a specific permittivity (e) in the range of from 1.0 to 4.0, as measured at a dielectric resonance frequency of 10 GHz by a dielectric resonator method (SPDR method), so that, for example, the semiconductor device can be used even in the frequency region lower than “5G”, and the cured product may have a specific permittivity (ε) in the range of from 1.5 to 3.0. Further, the cured product of the resin composition may have a dielectric loss tangent (tan δ) in the range of from 0.0001 to 0.01, and may have a dielectric loss tangent (tan δ) of 0.0005 to 0.005.

### Tensile Elongation (%)

The resin compositions in the Examples and Comparative Example were individually applied to a support made of polyethylene terephthalate (PET), and subjected to heat pretreatment (drying) in a nitrogen gas atmosphere at 130° C. for 10 minutes, and heated to dry the resin composition, and subjected to treatment (curing) in a nitrogen gas atmosphere at 200° C. for 60 minutes, forming a test specimen (sample) for measurement of a tensile elongation usable as an interlayer insulating film. The sample was formed into a film sample in a strip form having a width of 15 mm, a length of 200 mm, and a thickness of 30 μm. With respect to the film sample, using a table-top precision universal testing machine (Autograph AGS-J series, manufactured by Shimadzu Corporation), a tensile elongation at 25° C. was measured. The film sample was fixed by upper and lower fixtures of the table-top precision universal testing machine so that a length between the fixtures became 100 mm, and the film sample was pulled upwardly at a speed of 200 mm/minute, and an elongation was measured from a length at break. Specifically, a tensile elongation was determined from the following formula (1).

$$Elongation ( \% ) = [ Length at break ( mm ) - Initial length ( 100 mm ) ] / Initial length ( 100 mm ) \times 100 \qquad ( 1 )$$

### Coefficient of Linear Expansion (Ppm/K)

The resin compositions in the Examples and Comparative Example were individually applied to a support made of polyethylene terephthalate (PET), and subjected to heat pretreatment (drying) in a nitrogen gas atmosphere at 130° C. for 10 minutes, and heated to dry the resin composition, producing a resin film (sample film) having a width of 15 mm, a length of 200 mm, and a thickness of 30 μm. The produced resin film (sample) was stacked on another so that the resultant sample had a thickness of 100 μm, and cured at a temperature of 200° C. under a pressure of 1 MPa for 60 minutes, producing a sample for measurement of a coefficient of thermal expansion. With respect to the produced sample, measurement was conducted using a Thermomechanical Analyzer (TMA) by a tensile method, and an average coefficient of thermal expansion at 50 to 60° C. was obtained as reading (i.e., measured value of a coefficient of linear expansion). Conditions for the measurement were such that the sample was annealed at 20° C./min to 230° C. under a tensile load of 2 gf, and then cooled to room temperature, and then heated to 230° C. at 5° C./min and subjected to measurement. The measured coefficient of linear expansion (reading of average coefficient of thermal expansion) is a value in the plane direction (i.e., in the XY direction).

### Reliability Test

With respect to each of the resin compositions, reliability of a semiconductor device comprising an interlayer insulating film formed from a cured product obtained by curing the resin composition was evaluated.

A temporary tacking film (thermal release sheet, REVALPHA (registered trademark) 3195V, manufactured by Nitto Denko Corporation) was disposed on a silicon wafer having a thickness of 12 inches, and a plurality of semiconductor chips each having a size with a length of 5 mm and a width of 5 mm were disposed at intervals on the temporary tacking film.

Potting of a molding resin as an encapsulation material on the semiconductor chips was made. As the molding resin, a molding resin containing an epoxy resin and silicon dioxide (XLM8901-18, manufactured by Namics Corporation) was used. With respect to the cured product of the molding resin, a coefficient of linear expansion (CTEα1) of the cured product at a temperature lower than the glass transition temperature of the cured product was measured by the above-mentioned method. The cured product of the molding resin had a coefficient of linear expansion (CTEα1) of 10 ppm/° C. at a temperature lower than the glass transition temperature of the cured product. The molding resin around the semiconductor chips was molded by a compression molding method at 120° C. for 60 minutes. Then, the molding resin was cured in a heating oven (manufactured by TOWA CORPORATION) at 150° C. for 60 minutes, forming the semiconductor chips and encapsulation material in which the encapsulation material encapsulates the semiconductor chips, except one surface in contact with the temporary tacking film.

The molded semiconductor chips and encapsulation material were placed on a hotplate set at 200° C., and allowed to stand for 10 minutes, and the temporary tacking film and silicon wafer were removed.

In the molded encapsulation material and semiconductor chips, one surface of the semiconductor chips and the encapsulation material having the molding resin cured are adjacent to each other and present on substantially the same plane.

Each of the resin compositions in the Examples and Comparative Example was applied dropwise onto the surface on which the semiconductor chips and the encapsulation material are present on substantially the same plane so that the applied composition was directly in contact with both the semiconductor chips and the encapsulation material to apply the resin composition using a spin coater. In the application of each of the resin compositions in the Examples and Comparative Example, the rotational speed of the spin coater was 1,000 to 3,000 rpm, and the time of rotation was 5 to 30 seconds.

The semiconductor chips and encapsulation material, to which each of the resin compositions in the Examples and Comparative Example had been applied, were heated in a heating oven (manufactured by Isuzu Manufacturing Co., Ltd.) at 200° C. for 60 minutes to cure the resin composition, forming an interlayer insulating film having a thickness of 15 μm.

The encapsulation material and interlayer insulating film between the semiconductor chips were cut using a dicing saw into pieces of the encapsulation material and interlayer insulating film for each semiconductor chip, forming a sample for a semiconductor device of an FO-WLP type, containing an interlayer insulating film obtained by curing each of the resin compositions in the Examples and Comparative Example.

With respect to the sample, using a thermal shock tester, a thermal cycle test was conducted in which a cycle of heating and cooling at a temperature in the range of from −55 to +125° C. was repeated 500 times for 20 minutes per one cycle. A sample such that the interlayer insulating film was not removed after the thermal cycle test was rated “G (Good)”, and a sample such that the interlayer insulating film was removed after the test was rated “F (Fail)”.

TABLE 1

| | | | | Example | Example | Example | Example | Example | Example | Comparative |
|---|---|---|---|---|---|---|---|---|---|---|
| | | | | 1 | 2 | 3 | 4 | 5 | 6 | Example 1 |
| Component | A1 | Modified | OPE 2st 1200 | 7.5 | 12.5 | — | 7.5 | 6.1 | 6.1 | 17.5 |
| (A) | | polyphenylene ether | | | | | | | | |
| | A2 | Modified | OPE 2st 2200 | — | — | 9.0 | — | — | — | — |
| | | polyphenylene ether | | | | | | | | |
| | A3 | Modified | SA9000 | — | — | — | — | — | — | — |
| | | polyphenylene ether | | | | | | | | |
| Component | B1 | SBS | TR2827 | 17.5 | 12.5 | 21.0 | — | — | — | 7.5 |
| (B) | | H/S Ratio: 24/76 | | | | | | | | |
| | B2 | SBS | TR2003 | — | — | — | 17.5 | — | — | — |
| | | H/S Ratio: 43/57 | | | | | | | | |
| | B3 | SBBS | P1083 | — | — | — | — | 14.2 | — | — |
| | | H/S Ratio: 20/80 | | | | | | | | |
| | B4 | SBBS | P1500 | — | — | — | — | — | 14.2 | — |
| | | H/S Ratio: 30/70 | | | | | | | | |
| | B5 | XNBR | Nipol 1072 | — | — | — | — | — | — | — |
| | | H/S Ratio: 8/92 | | | | | | | | |
| | B6 | SEEPS | SEPTON 4033 | — | — | — | — | — | — | — |
| | | H/S Ratio: 30/70 | | | | | | | | |
| | B7 | SEBS | H1221 | — | — | — | — | — | — | — |
| | | H/S Ratio: 12/88 | | | | | | | | |
| | B8 | SEBS | G1652 | — | — | — | — | — | — | — |
| | | H/S Ratio: 30/70 | | | | | | | | |
| Component | C1 | Toluene | Boiling point: | — | — | — | — | 18.8 | 18.8 | — |
| (C) | | | 110.6° C. | | | | | | | |
| | C2 | Anone | Boiling point: | 75 | 75 | 70 | 75 | 60.9 | 60.9 | 75 |
| | | (Cyclohexanone) | 155.65° C. | | | | | | | |
| | C3 | Methyl ethyl ketone | Boiling point: | — | — | — | — | — | — | — |
| | | (MEK) | 79.64° C. | | | | | | | |
| Component | D1 | Organic peroxide | PERBUTYL Z | — | — | — | — | — | — | — |
| (D) | | | | | | | | | | |

| Total | | 100 | 100 | 100 | 100 | 100 | 100 | 100 |
|---|---|---|---|---|---|---|---|---|
| Evaluation | Solubility | G | G | G | G | G | G | G |
| | First viscosity 10 rpm (mPa · s) | 3438 | 1022 | 3800 | 1144 | 2565 | 1348 | 253.1 |
| | Second viscosity 1 rpm (mPa · s) | 3539 | 1099 | 3900 | 1193 | 2746 | 1481 | 302 |
| | Thixotropy index TI | 1.0 | 1.1 | 1.0 | 1.0 | 1.1 | 1.1 | 1.2 |
| | 1 rpm/10 rpm | | | | | | | |
| | Thickness of interlayer insulating | 9.4 | 5.1 | 14.2 | 5.7 | 13.7 | 7.4 | 7.2 |
| | film (μm) | | | | | | | |
| | Specific permittivity (ε) 10 GHz | 2.4 | 2.4 | 2.3 | 2.6 | 2.4 | 2.4 | 2.7 |
| | Dielectric loss tangent (tanδ) 10 GHz | 0.0028 | 0.0030 | 0.0024 | 0.0023 | 0.0010 | 0.0014 | 0.0028 |
| | Tensile elongation (%) | 128 | 34 | 62 | 74 | 442 | 56 | 12 |
| | Reliability test | G | G | G | G | G | G | F |

TABLE 2

| | | | | Example | Example | Example | Example | Example | Example | Example |
|---|---|---|---|---|---|---|---|---|---|---|
| | | | | 7 | 8 | 9 | 10 | 11 | 12 | 13 |
| Component | A1 | Modified | OPE 2st 1200 | 6 | 10 | 6 | 7.5 | 7.5 | 12.5 | — |
| (A) | | polyphenylene ether | | | | | | | | |
| | A2 | Modified | OPE 2st 2200 | — | — | — | — | — | — | — |
| | | polyphenylene ether | | | | | | | | |
| | A3 | Modified | SA9000 | — | — | — | — | — | — | 7.5 |
| | | polyphenylene ether | | | | | | | | |
| Component | B1 | SBS | TR2827 | — | — | — | 17.5 | — | — | 17.4 |
| (B) | | H/S Ratio: 24/76 | | | | | | | | |
| | B2 | SBS | TR2003 | — | — | — | — | — | — | — |
| | | H/S Ratio: 43/57 | | | | | | | | |
| | B3 | SBBS | P1083 | — | — | — | — | — | — | — |
| | | H/S Ratio: 20/80 | | | | | | | | |
| | B4 | SBBS | P1500 | — | — | — | — | — | — | — |
| | | H/S Ratio: 30/70 | | | | | | | | |
| | B5 | XNBR | Nipol 1072 | — | — | — | — | 17.5 | 12.5 | — |
| | | H/S Ratio: 8/92 | | | | | | | | |
| | B6 | SEEPS | SEPTON 4033 | 14 | — | — | — | — | — | — |
| | | H/S Ratio: 30/70 | | | | | | | | |
| | B7 | SEBS | H1221 | — | 10 | — | — | — | — | — |
| | | H/S Ratio: 12/88 | | | | | | | | |
| | B8 | SEBS | G1652 | — | — | 14 | — | — | — | — |
| | | H/S Ratio: 30/70 | | | | | | | | |
| Component | C1 | Toluene | Boiling point: | 80 | 80 | 80 | 75 | — | — | — |
| (C) | | | 110.6° C. | | | | | | | |
| | C2 | Anone | Boiling point: | — | — | — | — | 5 | 25 | 74.6 |
| | | (Cyclohexanone) | 155.65° C. | | | | | | | |
| | C3 | Methyl ethyl ketone | Boiling point: | — | — | — | — | 70 | 50 | — |
| | | (MEK) | 79.64° C. | | | | | | | |
| Component | D1 | Organic peroxide | PERBUTYL Z | — | — | — | — | — | — | 0.5 |
| (D) | | | | | | | | | | |

| Total | | 100 | 100 | 100 | 100 | 100 | 100 | 100 |
|---|---|---|---|---|---|---|---|---|
| Evaluation | Solubility | G | G | G | G | G | G | G |
| | First viscosity 10 rpm (mPa · s) | 1373 | 675 | 1023 | 751 | 1597 | 508.5 | 3385 |
| | Second viscosity 1 rpm (mPa · s) | 1249 | 680 | 836 | 570 | 1760 | 586 | 3196 |
| | Thixotropy index TI | 0.9 | 1.0 | 0.8 | 0.8 | 1.1 | 1.2 | 0.9 |
| | 1 rpm/10 rpm | | | | | | | |
| | Thickness of interlayer insulating | 13.4 | 6.3 | 7.5 | 10.5 | 8.3 | 7.1 | 8.0 |
| | film (μm) | | | | | | | |
| | Specific permittivity (ε) 10 GHz | 2.3 | 2.4 | 2.3 | 2.4 | 3.3 | 3.1 | 2.4 |
| | Dielectric loss tangent (tanδ) 10 GHz | 0.0009 | 0.0012 | 0.0007 | 0.0028 | 0.0180 | 0.0156 | 0.0029 |
| | Tensile elongation (%) | 238 | 97 | 258 | 89 | 333 | 205 | 449 |
| | Reliability test | G | G | G | G | G | G | G |

TABLE 3

| | | | | Example | Example | Example | Example |
|---|---|---|---|---|---|---|---|
| | | | | 14 | 15 | 16 | 17 |
| Component | A1 | Modified polyphenylene ether | OPE 2st 1200 | — | — | 10.2 | 7.6 |
| (A) | A2 | Modified polyphenylene ether | OPE 2st 2200 | — | 10.1 | — | |
| | A3 | Modified polyphenylene ether | SA9000 | 10.1 | — | — | — |
| Component | B1 | SBS H/S Ratio: 24/76 | TR2827 | — | — | — | — |
| (B) | B2 | SBS H/S Ratio: 43/57 | TR2003 | — | — | — | — |
| | B3 | SBBS H/S Ratio: 20/80 | P1083 | — | — | — | — |
| | B4 | SBBS H/S Ratio: 30/70 | P1500 | — | — | — | 3.0 |
| | B5 | XNBR H/S Ratio: 8/92 | Nipol 1072 | — | — | — | — |
| | B6 | SEEPS H/S Ratio: 30/70 | SEPTON 4033 | — | — | — | — |
| | B7 | SEBS H/S Ratio: 12/88 | H1221 | — | — | — | — |
| | B8 | SEBS H/S Ratio: 30/70 | G1652 | 11.9 | 11.9 | 12.8 | — |
| Component | C1 | Toluene | Boiling point: | 71.3 | 71.3 | 71.4 | 84.7 |
| (C) | | | 110.6° C. | | | | |
| | C2 | Anone (Cyclohexanone) | Boiling point: | — | — | — | — |
| | | | 155.65° C. | | | | |
| | C3 | Methyl ethyl ketone (MEK) | Boiling point: | — | — | — | — |
| | | | 79.64° C. | | | | |
| Component | D1 | Organic peroxide | PERBUTYL Z | — | — | — | — |
| (D) | D2 | Organic peroxide | PERCUMYL D | 0.2 | 0.2 | 0.5 | 0.2 |
| Component | E1 | Butadiene resin | B-1000 | — | — | — | 4.5 |
| (E) | | (1,2-vinyl structure: 85%) | | | | | |
| | E2 | Styrene-butadiene block copolymer | 1,2-SBS-L42 | — | — | 5.1 | — |
| | | (styrene: 20%; 1,2-vinyl structure: 90%) | | | | | |
| | E3 | Isocyanuric acid | L-DAIC | 6.5 | 6.5 | — | — |
| | | (Diallylated isocyanuric acid derivative) | | | | | |

| Total | | 100 | 100 | 100 | 100 |
|---|---|---|---|---|---|
| Evaluation | Solubility | G | G | G | G |
| | First viscosity 10 rpm (mPa · s) | 347 | 336 | 393 | 410 |
| | Second viscosity 1 rpm (mPa · s) | 328 | 362 | 408 | 230 |
| | Thixotropy index TI | 0.9 | 1.1 | 1.0 | 0.6 |
| | 1 rpm/10 rpm | | | | |
| | Specific permittivity (ε) 10 GHz | 2.4 | 2.4 | 2.4 | 2.4 |
| | Dielectric loss tangent (tanδ) 10 GHz | 0.0011 | 0.0009 | 0.0013 | 0.0019 |
| | Tensile elongation (%) | 54 | 99 | 41 | 15 |
| | Coefficient of linear expansion (ppm/K) | 145 | 140 | 131 | 97 |
| | Reliability test | G | G | G | G |

As can be seen from Tables 1, 2, and 3, the cured products obtained by curing the resin compositions in Examples 1 to 17 have a tensile elongation of 15% or more at 25° C. With respect to the cured products obtained by curing the resin compositions in Examples 1 to 17, the interlayer insulating film was not removed after the thermal cycle test, and the cured products were rated “G (good)”. When the cured products obtained by curing the resin compositions in Examples 1 to 17 are used as an interlayer insulating film of the rewiring layer for a semiconductor device of an FO-WLP type, which film is directly in contact with at least part of the semiconductor chip and at least part of the encapsulation material, the interlayer insulating film absorbs expansion and shrinkage of the semiconductor chips and the encapsulation material having different coefficients of linear expansion due to thermal cycling, so that a removal of and formation of a crack in the semiconductor chips and the encapsulation material, formation of a crack in the wiring contained in the rewiring layer, and the like can be suppressed.

As seen from Tables 1, 2, and 3, the cured products obtained by curing the resin compositions in Examples 1 to 10 and 13 to 17 have a specific permittivity (e) of 1.5 to 3.0 and a dielectric loss tangent (tan δ) of 0.001 to 0.010, as measured at a dielectric resonance frequency of 10 GHz by a dielectric resonator method (SPDR method), and thus have satisfactorily excellent electrical properties as an interlayer insulating film of the rewiring layer for a semiconductor device which is used in a high frequency region for, for example, fifth-generation mobile communications system “5G”. Further, as seen from Table 2, the cured products obtained by curing the resin compositions in Examples 11 and 12, in which an XNBR (carboxylated nitrile butadiene rubber) was used as the elastomer as component (B), have excellent electrical properties as an interlayer insulating film of the rewiring layer for a semiconductor device which can be used, for example, even in the frequency region lower than “5G”.

As seen from Tables 1, 2, and 3, with respect to the resin compositions in Examples 1 to 17, when containing the component (A), component (B), and component (E), the solubility of the component (E) in the component (C) is excellent, and, in the case where the resin composition is applied to the semiconductor chips and the encapsulation material using a spin coater, a film having a substantially uniform thickness can be formed. The resin compositions in Examples 1 to 13 had a first viscosity in the range of from 300 to 4,000 mPa·s, as measured at 25° C. and at 10 rpm using a rotational viscometer, and had a second viscosity in the range of from 200 to 4,200 mPa·s, as measured at 25° C. and at 1 rpm. Further, the resin compositions in Examples 1 to 17 had a thixotropy index TI in the range of from 0.5 to 3.0, in terms of the ratio of the second viscosity to the first viscosity. With respect to the resin compositions in Examples 1 to 17, even in the case where the resin composition is applied using a spin coater so as to be directly in contact with both the semiconductor chips and the encapsulation material, a film having a substantially uniform thickness that has less unevenness can be formed.

As can be seen from Table 3, the samples (film samples) obtained by curing the resin compositions in Examples 14 to 17 have a coefficient of linear expansion at 50 to 60° C. of 200 ppm/K or less, specifically, 150 ppm/K or less, and the interlayer insulating film formed from the resin composition absorbs expansion and shrinkage of the semiconductor chips and the encapsulation material due to thermal cycling, so that a removal of the semiconductor chips and the encapsulation material is suppressed, and formation of a crack in the wiring contained in the rewiring layer and the like can be suppressed. With respect to the samples (film samples) obtained by curing the resin compositions in Examples 14 to 17, the interlayer insulating film was not removed after the thermal cycle test, and the samples were rated “G (good)”.

The resin composition in Comparative Example 1 has a first viscosity of less than 300 mPa's and does not contain the component (E), and therefore the cured product obtained by curing the resin composition has a tensile elongation as small as less than 15% at 25° C. The cured product (interlayer insulating film of the sample) obtained by curing the resin composition in Comparative Example 1 was removed after the thermal cycle test, and rated “F (Fail)”. The cured product obtained by curing the resin composition in Comparative Example 1 is unlikely to be able to satisfactorily absorb expansion and shrinkage of the semiconductor chips and the encapsulation material having different coefficients of linear expansion due to thermal cycling to suppress a removal of the materials, and thus the cured product is not suitable for an interlayer insulating film of the rewiring layer for a semiconductor device of an FO-WLP type.

As can be seen from Table 1, with respect to the resin composition in Comparative Example 1, the solubility of the component (A) and component (B) in the component (C) was excellent, but the resin composition had a first viscosity of less than 300 mPa·s, as measured at 25° C. and at 10 rpm using a rotational viscometer, and therefore, in the case where the resin composition is applied to the semiconductor chips and the encapsulation material using a spin coater, the resultant film of the resin composition had an uneven thickness.

### INDUSTRIAL APPLICABILITY

The resin composition and semiconductor device according to an embodiment of the present disclosure, or an interlayer insulating film obtained by curing the resin composition, or a semiconductor device comprising the interlayer insulating film can be used in a semiconductor device of a wafer level package (WLP) type, particularly of an FO-WLP type. The semiconductor device according to an embodiment of the present disclosure can be used in electronic parts for electronic devices, such as a mobile phone, a smartphone, a laptop computer, a tablet terminal, and a camera module.

1. A semiconductor device comprising:
a semiconductor chip,
an encapsulation material for covering the semiconductor chip, and
a rewiring layer comprising a wiring for electrically connecting the semiconductor chip and an external terminal, and an interlayer insulating film for covering a portion around the wiring,
wherein the rewiring layer has an area larger than that of the semiconductor chip in a plan view, and
wherein the interlayer insulating film has a tensile elongation of 15% or more at 25° C.

2. The semiconductor device according to claim 1, wherein the interlayer insulating film is directly in contact with at least part of the semiconductor chip and at least part of the encapsulation material.

3. The semiconductor device according to claim 1, wherein at least part of the semiconductor chip and at least part of the encapsulation material are adjacent to each other and present on the same plane, wherein the interlayer insulating film is directly in contact with at least part of the semiconductor chip and at least part of the encapsulation material which are present on the same plane.

4. The semiconductor device according to claim 1, wherein the interlayer insulating film has a dielectric loss tangent (tan δ) of 0.010 or less, as measured at a dielectric resonance frequency of 10 GHz.

5. The semiconductor device according to claim 1, wherein the interlayer insulating film is formed from a resin composition comprising a thermosetting resin having an unsaturated double bond at the end thereof.

6. The semiconductor device according to claim 1, wherein the interlayer insulating film is formed from a resin composition comprising a polyphenylene ether having an unsaturated double bond at the end thereof, and an elastomer.

7. The semiconductor device according to claim 1, wherein the interlayer insulating film is formed from a resin composition comprising a polyphenylene ether having an unsaturated double bond at the end thereof, and an elastomer, wherein the ratio of a hard segment and a soft segment contained in the elastomer is 1:99 to 45:55.

8. The semiconductor device according to claim 6, wherein the elastomer is a styrene thermoplastic elastomer.

9. The semiconductor device according to claim 1, wherein the encapsulation material comprises an epoxy resin.

10. A resin composition for a semiconductor device of a wafer level package type, the resin composition comprising:
(A) a thermosetting resin having an unsaturated double bond at the end thereof, and
(B) an elastomer,
wherein a cured product of the resin composition has a tensile elongation of 15% or more at 25° C.

11. The resin composition according to claim 10, further comprising (C) a solvent.

12. The resin composition according to claim 11, which has a first viscosity in the range of from 300 to 4,000 mPa·s, as measured at 25° C. and at 10 rpm using a rotational viscometer.

13. The resin composition according to claim 12, which has a second viscosity in the range of from 200 to 4,200 mPa·s, as measured at 25° C. and at 1 rpm using a rotational viscometer, and which has a thixotropy index TI of 0.5 to 3.0, in terms of the ratio of the second viscosity to the first viscosity.

14. The resin composition according to claim 10, wherein the amount of the component (B) contained in the resin composition is 25 to 90% by mass, based on the total mass of the components (A) and (B) (100% by mass).

15. A semiconductor device comprising an interlayer insulating film obtained by curing the resin composition according to claim 10, which is placed around a wiring for electrically connecting a semiconductor chip and an external terminal.
